(19) United States
(12) Patent Application Publication
(10) Pub. No.: US 2026/0150675 A1
(43) Pub. Date: May 28, 2026

(54) PACKAGE STRUCTURE WITH THERMAL INTERFACE MATERIAL AND METHOD FOR MANUFACTURING THE SAME

(71) Applicant: Taiwan Semiconductor Manufacturing Company, Ltd., Hsinchu (TW)

(72) Inventors: Bang-Li WU, Hsinchu City (TW); Chien-Chang WANG, Hsinchu City (TW); Ching WANG, Taichung City (TW); Kuo-Chin CHANG, Chiayi City (TW); Kathy Wei YAN, Hsinchu (TW); Jun HE, Zhubei City, Hsinchu County (TW)

(73) Assignee: Taiwan Semiconductor Manufacturing Company, Ltd., Hsinchu (TW)

(21) Appl. No.: 18/956,683

(22) Filed: Nov. 22, 2024

(51) Int. Cl. H01L 23/373; H01L 23/00; H01L 23/367; H01L 25/065

(52) U.S. Cl. CPC H10W 40/255; H10W 40/22; H10W 72/073; H10W 72/324; H10W 72/334; H10W 72/387; H10W 90/00; H10W 90/734

(57) ABSTRACT

A package structure and method for manufacturing the same are provided. The package structure includes a package component and a protruding feature attached to the package component. The package structure further includes a lid disposed over the package component and the protruding feature and a first thermal interface material under a bottom surface of the lid and at a first side of the protruding feature. The package structure includes a second thermal interface material. In addition, the second thermal interface material includes a first portion under the bottom surface of the lid and at a second side of the protruding feature, a second portion over a bottom portion of the lid, and a third portion through the bottom portion of the lid and connecting with the first portion and the second portion.

### BACKGROUND

The semiconductor integrated circuit (IC) industry has experienced rapid growth. Continuing advances in semiconductor manufacturing processes have resulted in semiconductor devices with finer features and/or higher degrees of integration. Functional density (i.e., the number of interconnected devices per chip area) has generally increased while feature sizes (i.e., the smallest component that can be created using a fabrication process) have decreased. This scaling-down process generally provides benefits by increasing production efficiency and lowering associated costs.

A chip package not only provides protection for semiconductor devices from environmental contaminants, but also provides a connection interface for the semiconductor devices packaged therein. Smaller package structures, which take up less space or are lower in height, have been developed to package the semiconductor devices.

New packaging technologies have been developed to further improve the density and functionality of semiconductor dies. These relatively new types of packaging technologies for semiconductor dies face manufacturing challenges.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A to 1Q illustrate cross-sectional views of intermediate stages of manufacturing a package structure in accordance with some embodiments.

FIG. 1B-1 illustrates a first layout of the semiconductor dies over the interconnect structure in accordance with some embodiments.

FIG. 1B-2 illustrates a second layout of the semiconductor dies over the interconnect structure in accordance with some embodiments.

FIG. 1H-1 illustrates a protruding feature formed over the package component with the first layout in accordance with some embodiments.

FIG. 1H-2 illustrates the protruding feature formed over the package component with the second layout in accordance with some embodiments.

FIG. 1H-3 illustrates a protruding feature formed over the package component with the first layout in accordance with some embodiments.

FIG. 1H-4 illustrates the protruding feature formed over the package component with the second layout in accordance with some embodiments.

FIG. 1I-1 illustrates a top view of the TIMs around the protruding feature over the package component in accordance with some embodiments.

FIG. 1I-2 illustrates a top view of the TIMs around the protruding feature over the package component in accordance with some embodiments.

FIG. 1K-1 illustrates a top view of a lid with the perforated holes over the protruding feature in accordance with some embodiments.

FIG. 1K-2 illustrates a top view of the lid with the perforated holes over the protruding feature in accordance with some embodiments.

FIG. 1K-3 illustrates a top view of a lid with the perforated hole over the protruding feature in accordance with some embodiments.

FIG. 1K-4 illustrates a top view of the lid with the perforated hole over the protruding feature in accordance with some embodiments.

FIG. 1L-1 illustrates that the TIM is applied to the region by applying the TIM through one of the perforated holes in accordance with some embodiments.

FIG. 1L-2 illustrates that the TIM is applied to the region by applying the TIM through all of the perforated holes in accordance with some embodiments.

FIG. 1L-3 illustrates that the TIM is applied to the region by applying the TIM through the perforated hole in the central region of the lid in accordance with some embodiments.

FIGS. 1L-4 and 1L-5 illustrate that the TIM is applied to the region by applying the TIM to the trench in accordance with some embodiments.

FIGS. 2A and 2B illustrate cross-sectional views of some of the intermediate stages of manufacturing the package structure in accordance with some other embodiments.

FIGS. 3A to 3C illustrate cross-sectional views of intermediate stages of manufacturing a package structure in accordance with some embodiments.

FIG. 4 illustrates a cross-sectional view of a package structure in accordance with some embodiments.

FIG. 5 illustrates a cross-sectional view of a package structure in accordance with some embodiments.

FIG. 6 illustrates a cross-sectional view of a package structure in accordance with some embodiments.

FIG. 7 illustrates a cross-sectional view of a package structure in accordance with some embodiments.

FIGS. 8A to 8C illustrate cross-sectional views of intermediate stages of manufacturing a package structure in accordance with some embodiments.

FIG. 9 illustrates a cross-sectional view of a package structure in accordance with some embodiments.

FIG. 10A illustrates a cross-sectional view of a package structure in accordance with some embodiments.

FIG. 10B illustrates a cross-sectional view of a package structure in accordance with some embodiments.

FIG. 11A illustrates a cross-sectional view of a package structure in accordance with some embodiments.

FIG. 11B illustrates a cross-sectional view of a package structure in accordance with some embodiments.

FIGS. 12A and 12B illustrate cross-sectional views of intermediate stages of manufacturing a package structure in accordance with some embodiments.

FIG. 12A-1 illustrates a top view of the TIM around the protruding feature over the package component in accordance with some embodiments.

FIG. 12A-2 illustrates a top view of the TIM around the protruding feature over the package component in accordance with some embodiments.

FIG. 13 illustrates a cross-sectional view of a package structure in accordance with some embodiments.

FIG. 14A illustrates a cross-sectional view of a package structure in accordance with some embodiments.

FIG. 14B illustrates a cross-sectional view of a package structure in accordance with some embodiments.

FIG. 15A illustrates a cross-sectional view of a package structure in accordance with some embodiments.

FIG. 15B illustrates a cross-sectional view of a package structure in accordance with some embodiments.

FIG. 16A illustrates a cross-sectional view of a package structure in accordance with some embodiments.

FIG. 16B illustrates a cross-sectional view of a package structure in accordance with some embodiments.

FIG. 17A illustrates a cross-sectional view of a package structure in accordance with some embodiments.

FIG. 17B illustrates a cross-sectional view of a package structure in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of the disclosure may relate to package structures such as three-dimensional (3D) packaging, 3D-IC devices, and 2.5D packaging. Embodiments of the disclosure form a package structure including a substrate that carries one or more dies or packages and a protective element (such as a protective lid) aside the dies or packages. The protective element may also function as a warpage-control element and/or heat dissipation element.

Other features and processes may also be included. For example, testing structures may be included to aid in the verification testing of the 3D packaging, 3DIC devices, and/or 2.5 D packaging. The testing structures may include, for example, test pads formed in a redistribution layer or on a substrate that allows testing to be conducted using probes or probe cards and the like. Verification testing may be performed on intermediate structures as well as the final structure. Additionally, the structures and methods disclosed herein may be used in conjunction with testing methodologies that incorporate intermediate verification of known good dies to increase the yield and decrease costs.

A package structure may include a package component, and the package component may include one or more semiconductor dies. The semiconductor dies may generate heat during the operation. In addition, as the power consumption of the advanced package increases, better heat spreading ability may be required. Accordingly, in the embodiments of present application, thermal interface materials (TIM) are applied to the package component in a novel way, so that the temperature at the semiconductor dies may be spread (e.g. dissipated) through the TIM more efficiently. Therefore, the temperature of the package components may be decreased during operation.

More specifically, a liquid TIM, which is in a liquid form at room temperature, may have high thermal conductivity to help spreading the heat and may be applied to the package component. However, when the liquid TIM is applied to the package component, the liquid TIM may flow to other regions due to high fluidity at the room temperature and the performance of the resulting device may therefore be undermined. Accordingly, in the embodiments of the present application, a protruding feature is formed over the package component to surround the liquid TIM, so that the leakage of the liquid TIM may be prevented. In addition, an adhesive TIM may also be applied to the periphery region of the package component to further prevent the leakage of the liquid TIM. Furthermore, a gel TIM may be applied between the adhesive TIM and the protruding feature, and the gel TIM may have a relatively good thermal conductivity while less fluidity (e.g. compared to the liquid TIM), so that the heat spreading ability may be improved but the risk of the leakage of the TIM may be reduced.

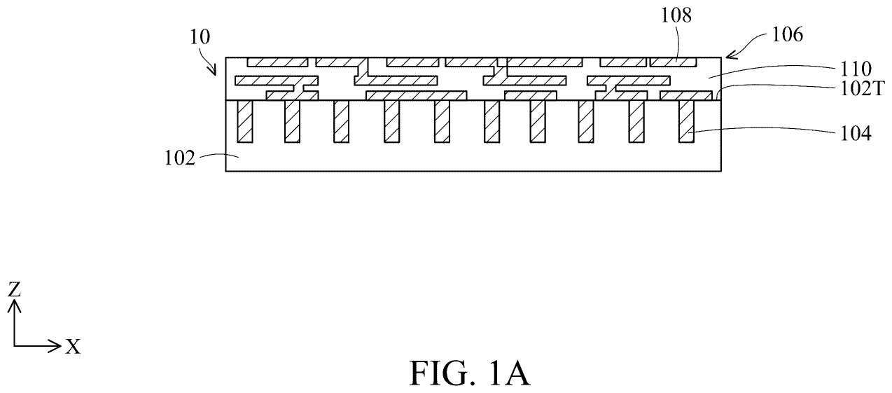

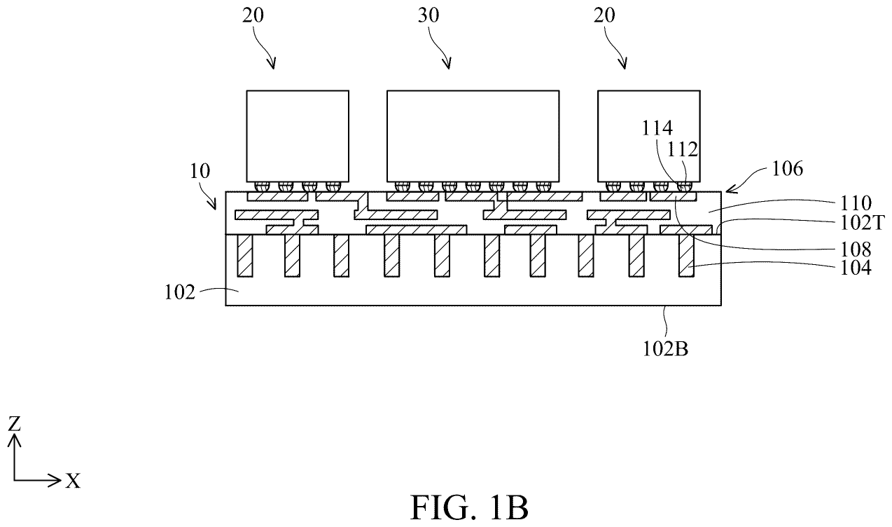

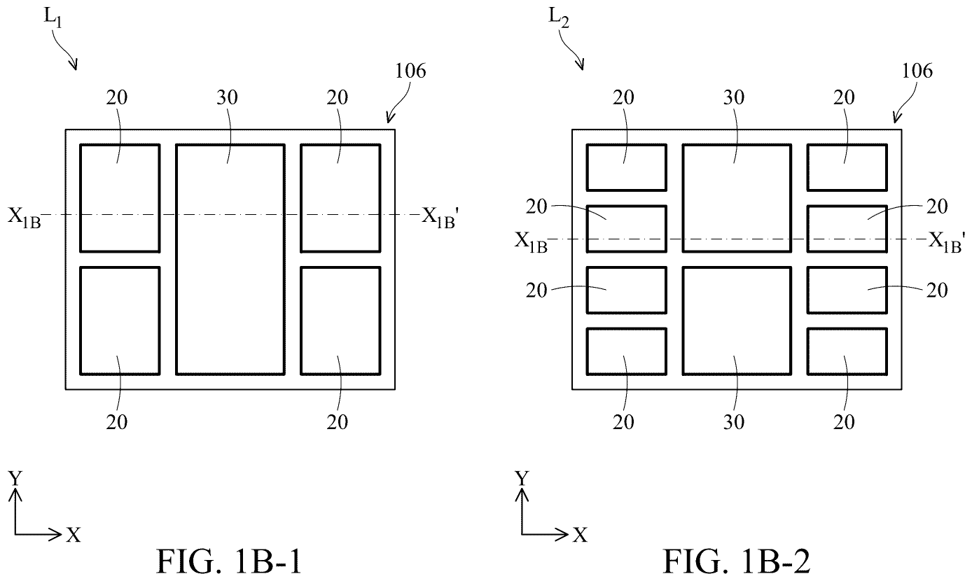

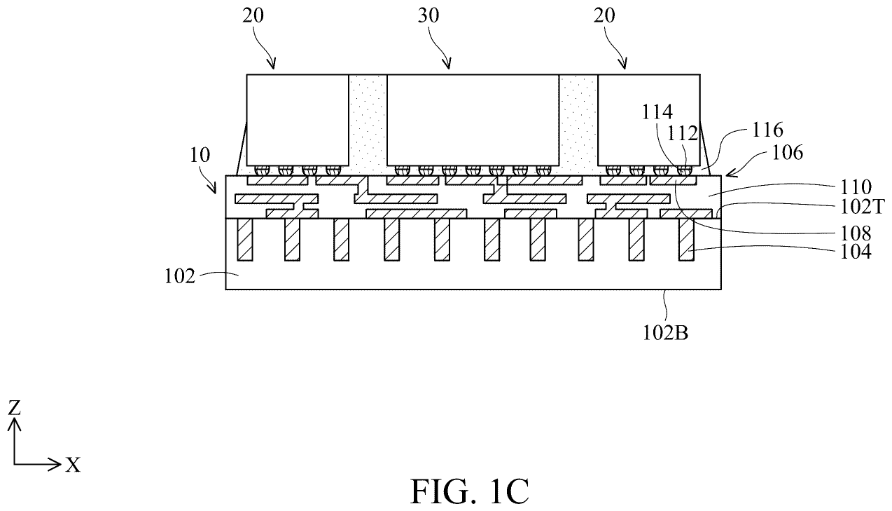

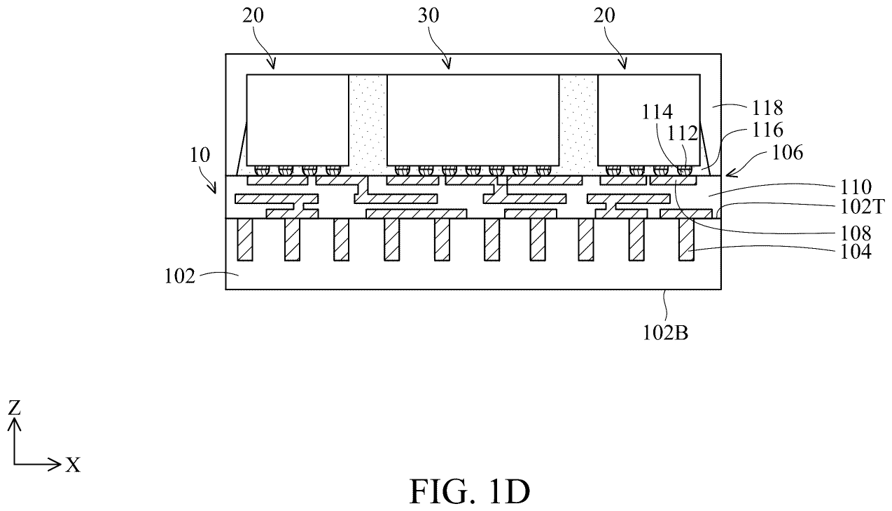

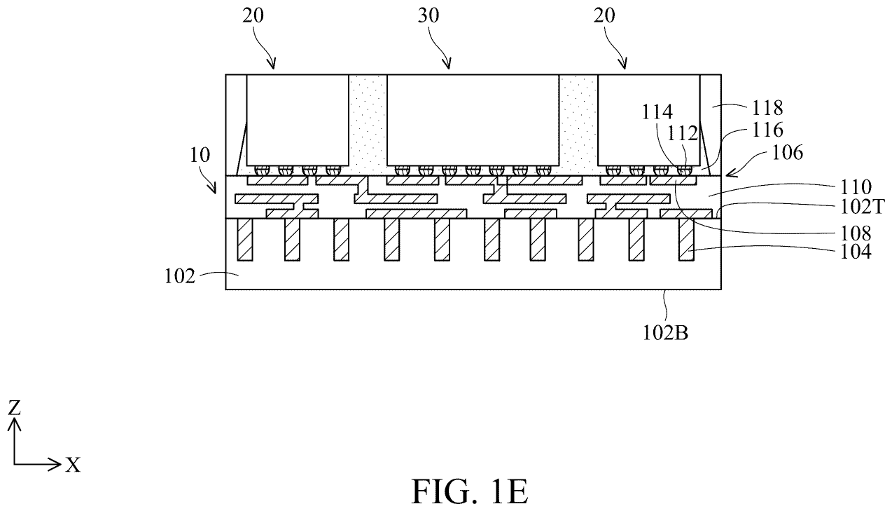

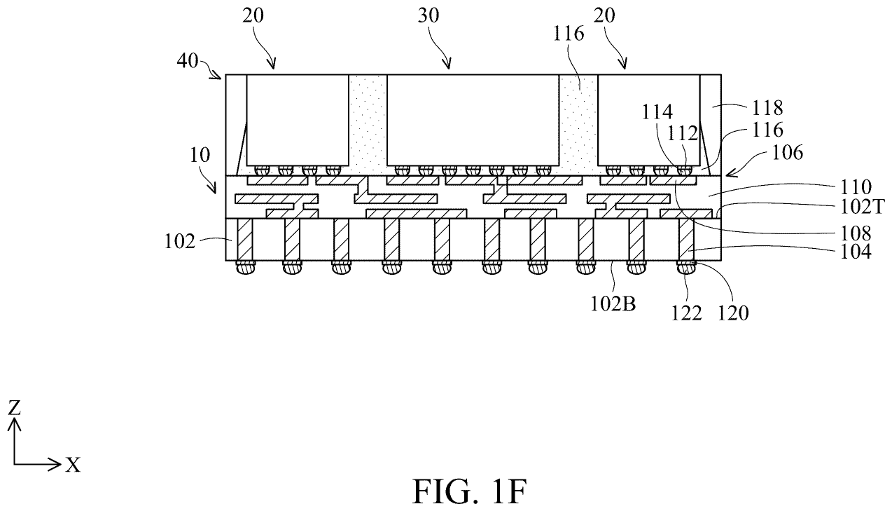

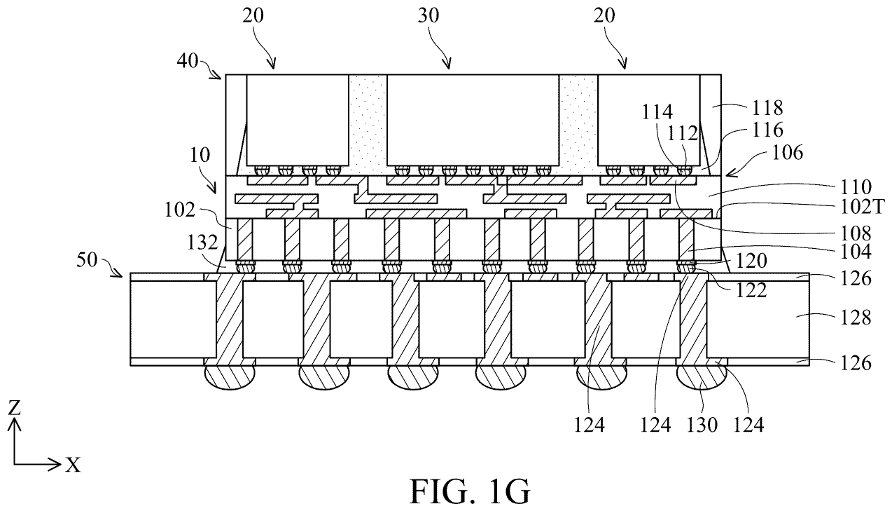

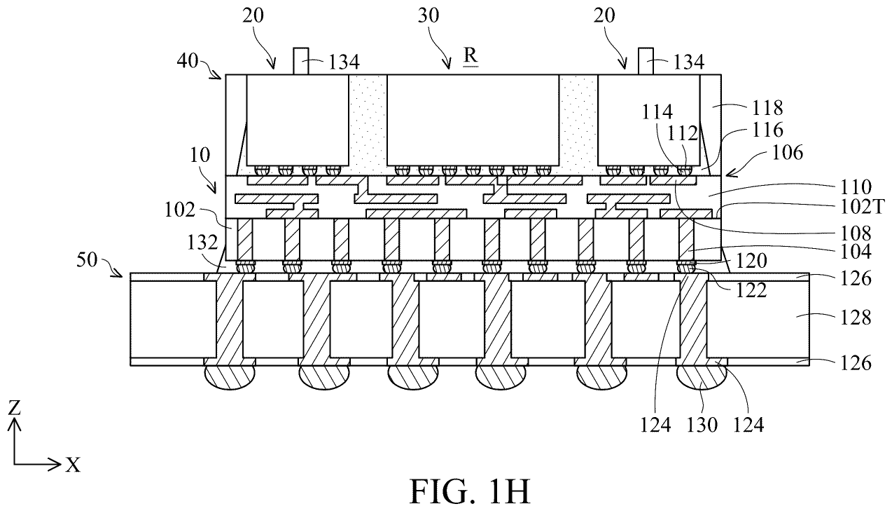

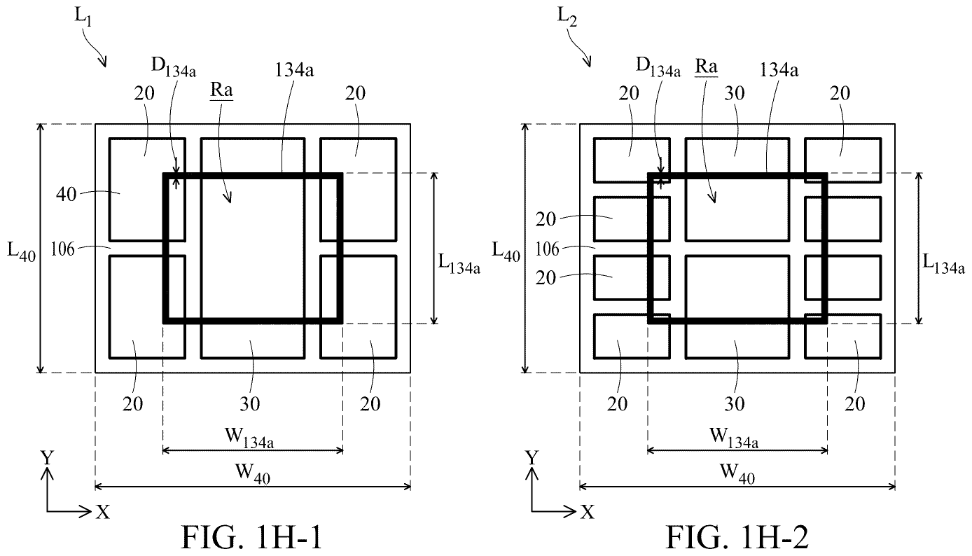

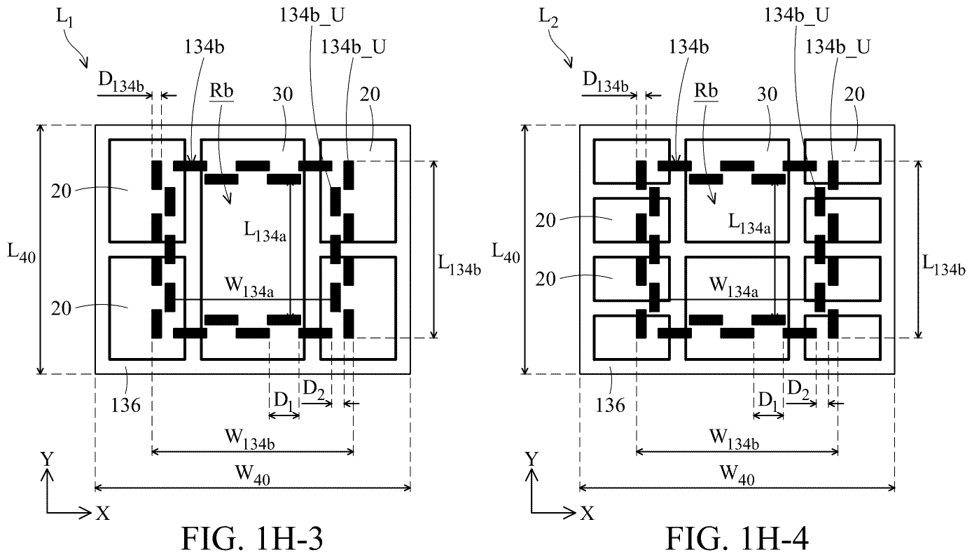

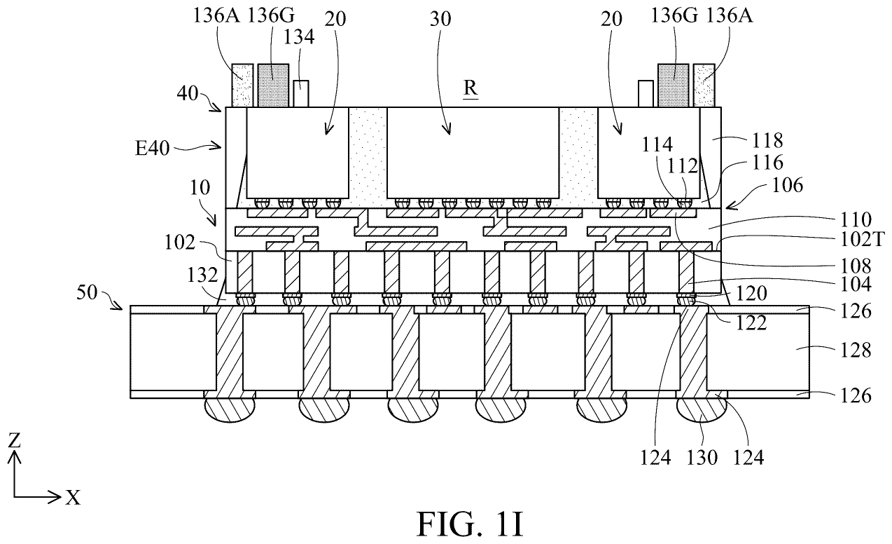

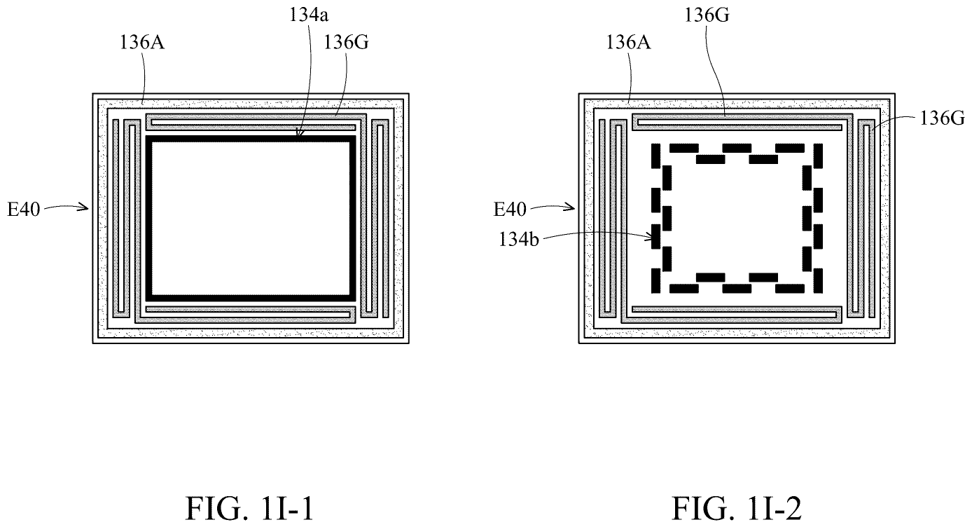

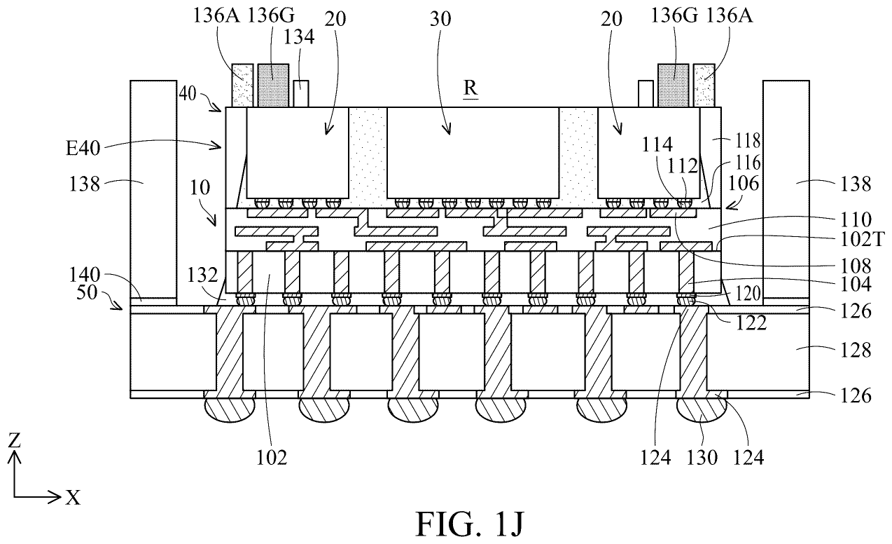

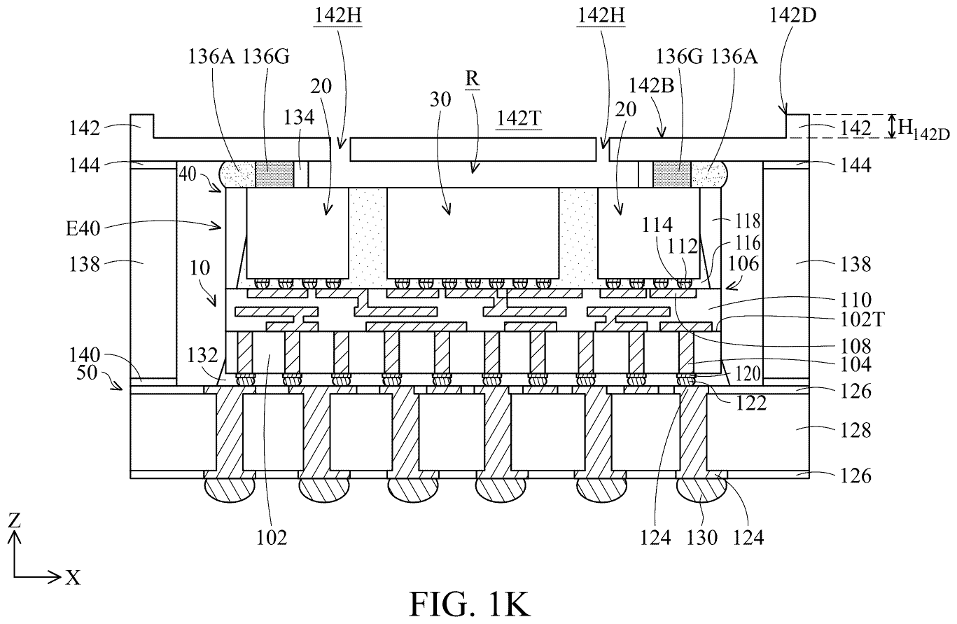

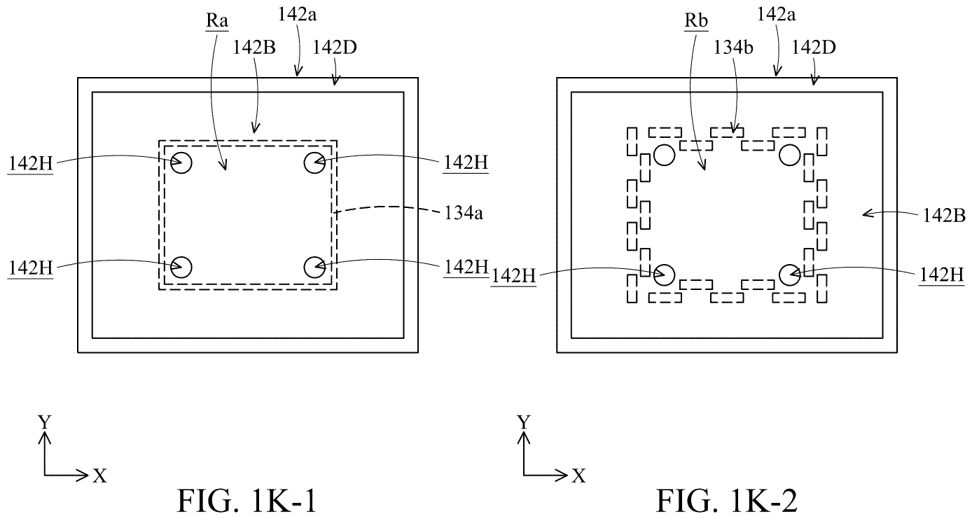

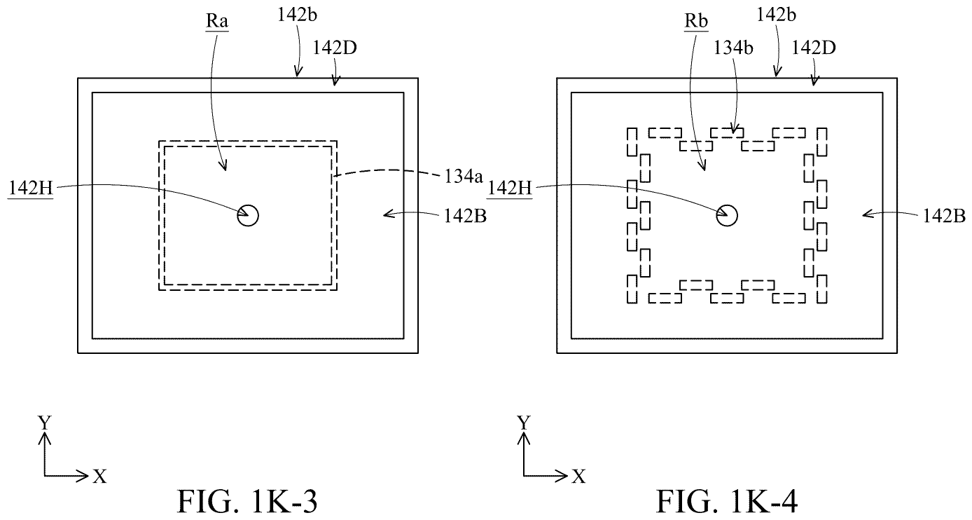

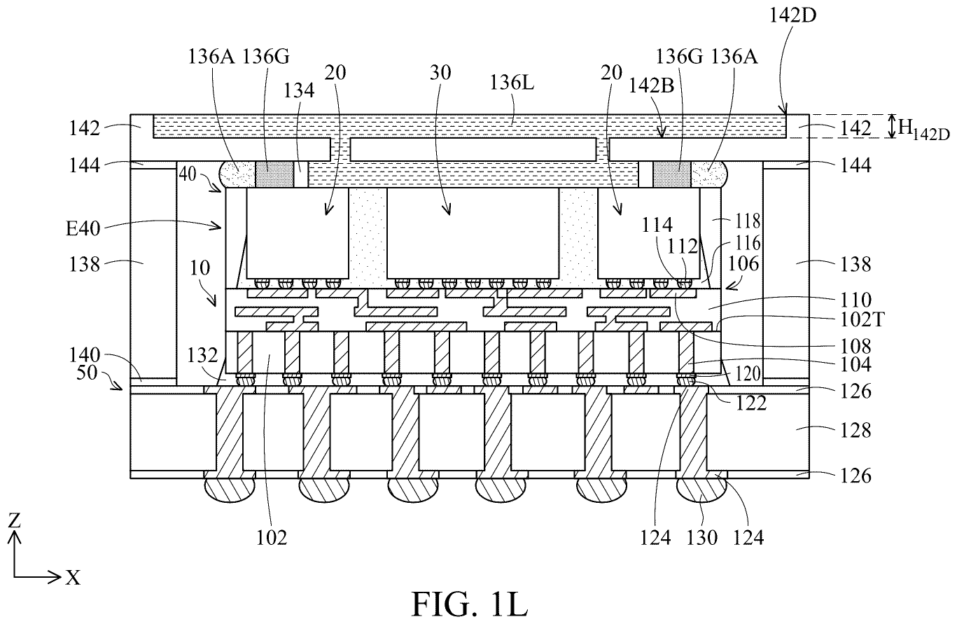

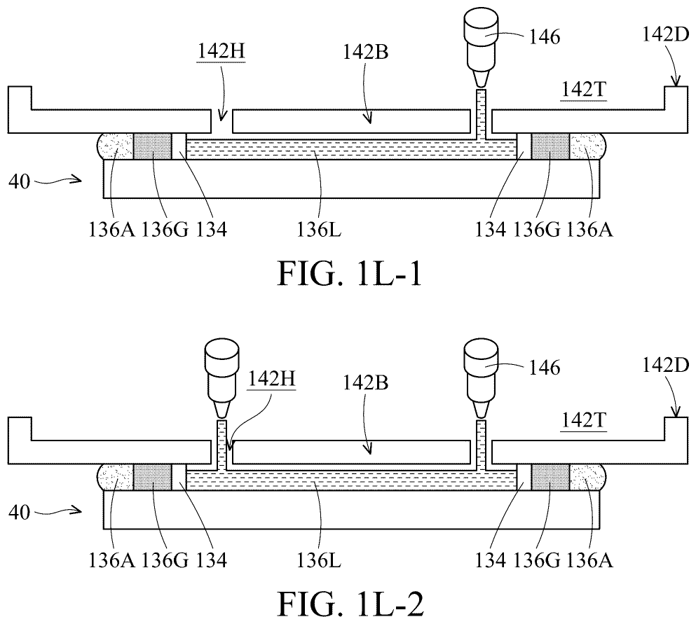

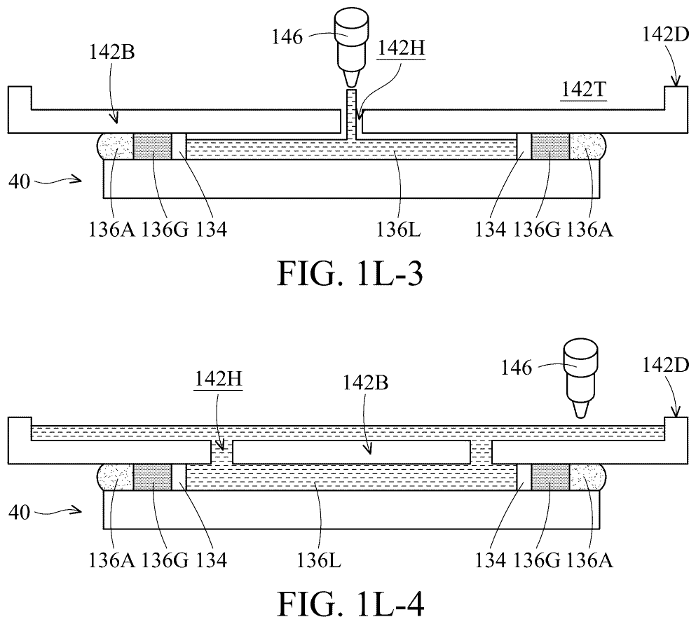

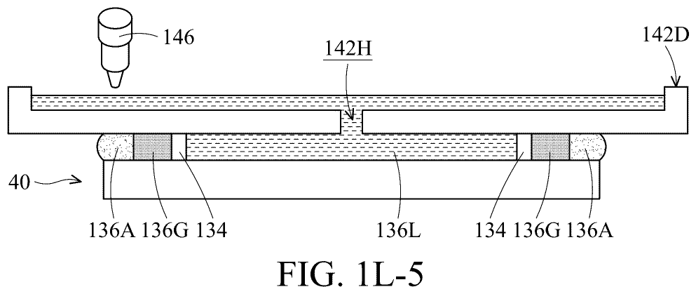

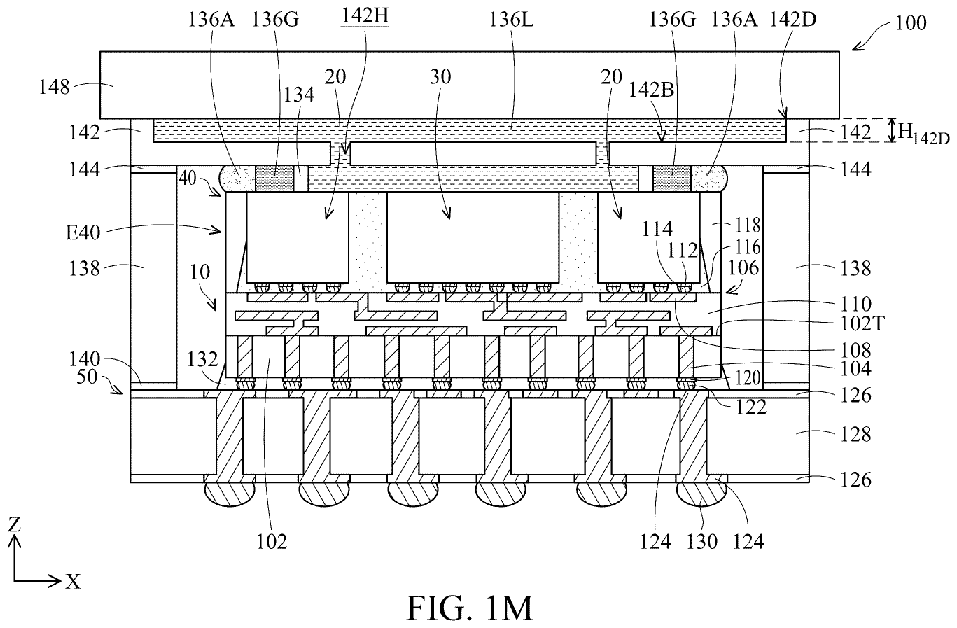

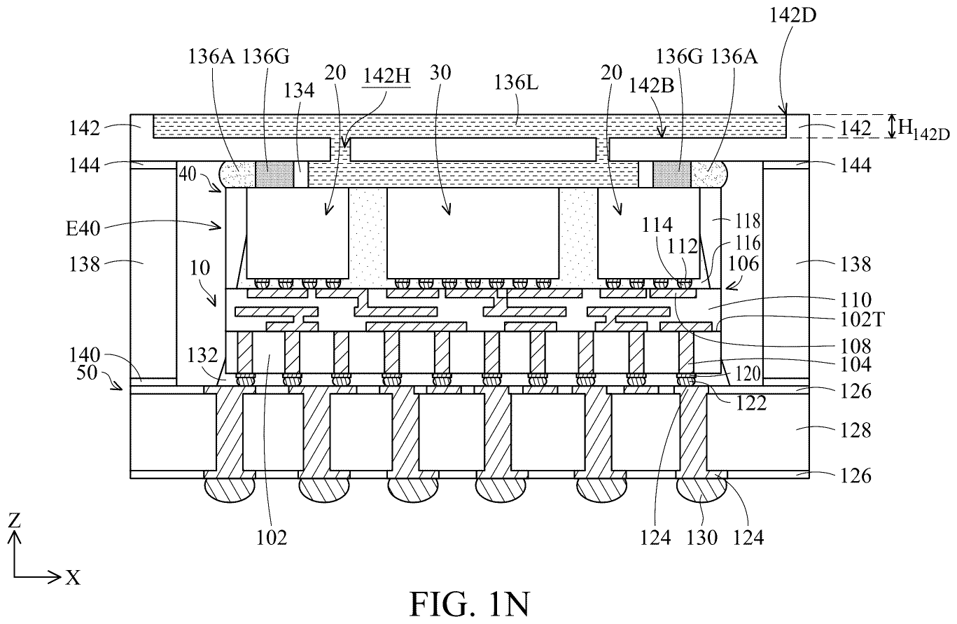

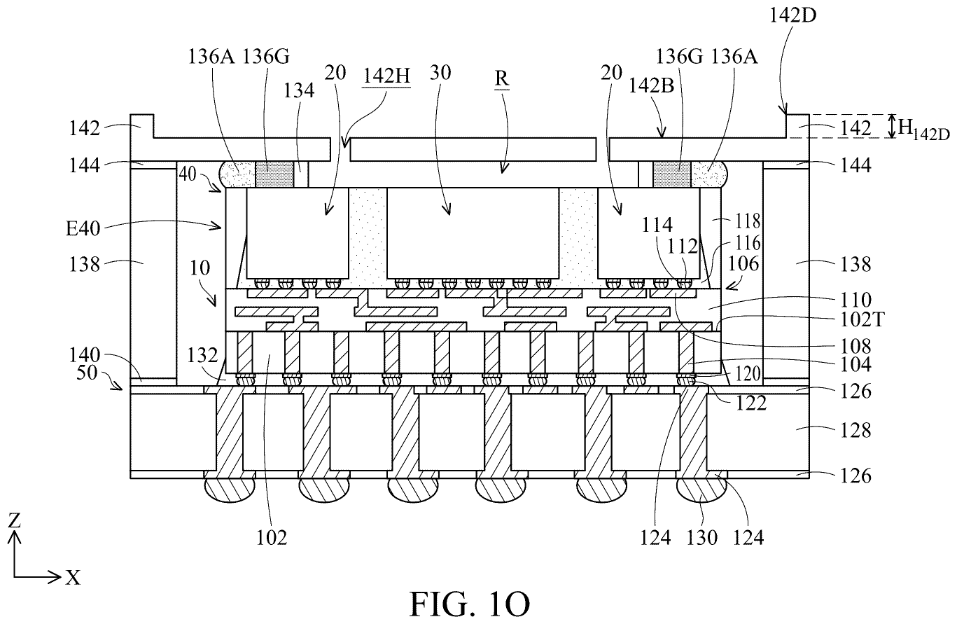

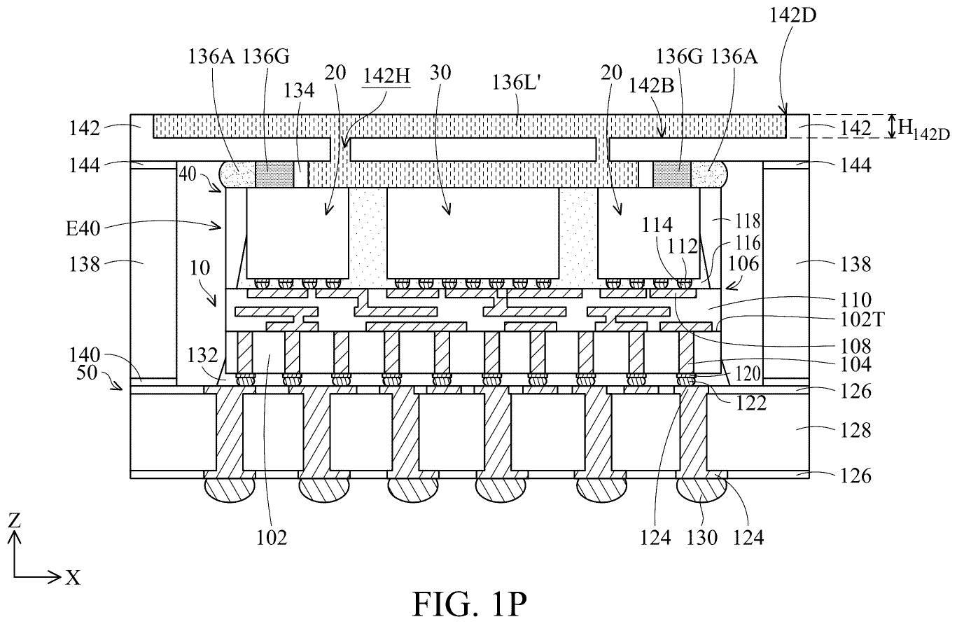

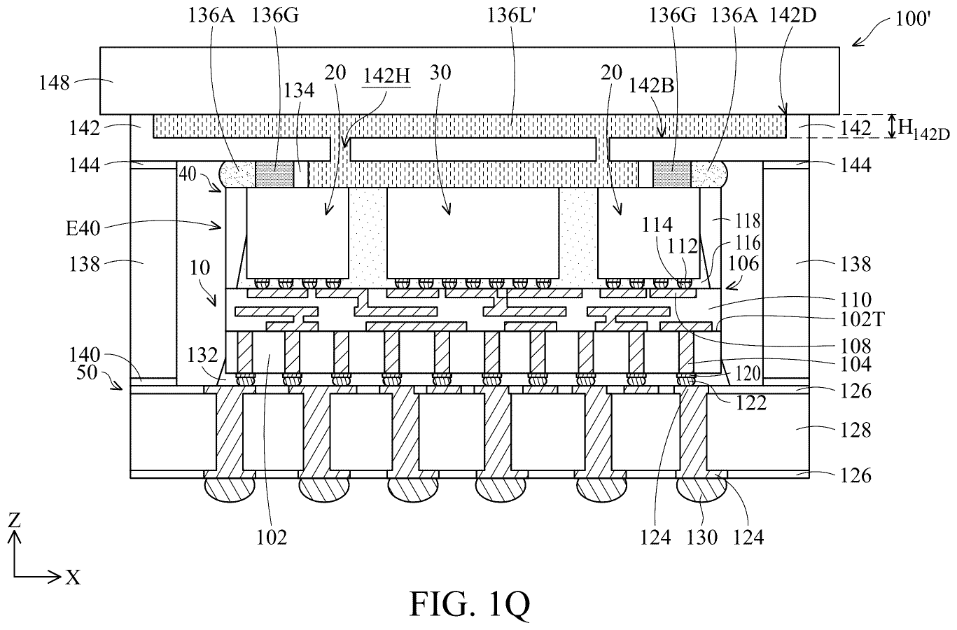

FIGS. 1A to 1Q illustrate cross-sectional views of intermediate stages of manufacturing a package structure 100 in accordance with some embodiments. For a better understanding of the structure, the X-Y-Z coordinate reference is provided in the following figures. In addition, the following figures may have been simplified for the sake of clarity to better understand the inventive concepts of the present disclosure. Additional features may be included, and some of the features described below may be replaced, modified, or eliminated.

First, an interposer structure 10 may be formed. As shown in FIG. 1A, the interposer structure 10 includes through vias 104 formed in a substrate 102 and an interconnect structure 106 formed over the substrate 102 in accordance with some embodiments.

The substrate 102 may be a wafer, such as a silicon wafer, although other substrates, such as a silicon-on-insulator (SOI) substrate, a multi-layered substrate, or a gradient substrate may also be used. The substrate 102 may be doped (e.g., with a p-type or an n-type dopant) or undoped. In some embodiments, the semiconductor material of the substrate 102 may include silicon, germanium, a compound semiconductor including silicon carbide, gallium arsenide, gallium phosphide, indium phosphide, indium arsenide, and/or indium antimonide, an alloy semiconductor including silicon-germanium, gallium arsenide phosphide, aluminum indium arsenide, aluminum gallium arsenide, gallium indium arsenide, gallium indium phosphide, and/or gallium indium arsenide phosphide, or combinations thereof. In some other embodiments, the substrate 102 may be a dielectric material.

The through vias 104 are formed in the substrate 102 and the top surfaces of the through vias 104 are exposed from a first side 102T of the substrate 102, as shown in FIG. 1A in accordance with some embodiments. The through vias 104 may be formed by forming trenches from the first side 102T of the substrate 102 and downwardly extending into the substrate 102. The trenches may be formed using acceptable photolithography and etching techniques, such as by forming and patterning a photoresist and then performing an etching process using the patterned photoresist as an etching mask. The etching process may include a dry etching process and/or a wet etching process. A conductive material may then be formed in the trenches, thereby forming the through vias 104. In some embodiments, a liner (not shown) may be deposited in the openings prior to forming the conductive material. The conductive material may include a metal or a metal alloy such as copper, silver, gold, tungsten, cobalt, aluminum, alloys thereof, or the like. A planarization process (e.g., a CMP process or a grinding process) may be performed to remove excess conductive material along the top surface of the substrate 102, such that the top surfaces of the through vias 104 and the substrate 102 at the first side 102T are substantially level. As shown in FIG. 1A, the bottom portions of the through vias 104 are still embedded in the substrate 102 at this step in accordance with some embodiments. That is, the bottom surface of the through vias 104 are not exposed from the second side 102B of the substrate 102 in accordance with some embodiments.

After the through vias 104 are formed, the interconnect structure 106 is formed over the substrate 102, as shown in FIG. 1A in accordance with some embodiments. In some embodiments, the interconnect structure 106 includes one or more layers of conductive features 108 formed in one or more dielectric layers 110. The conductive features 108 are electrically connected to the through vias 104 in accordance with some embodiments.

The conductive features 108 may include conductive lines, conductive vias, conductive pads, metallization patterns, redistribution layers, or the like that provide electrical interconnections and electrical routing. In some embodiments, the conductive features 108 include conductive pads (not illustrated) at a top surface of the interconnect structure 106. The conductive pads may be metal pads, bond pads, Under-Bump Metallizations (UBMs), or the like. In some embodiments, the interconnect structure 106 may have multiple layers of conductive features 108, but the precise number of layers of conductive features 108 may be dependent upon the design of the interconnect structure 106. In some embodiments, the bottommost one layer of the conductive features is in direct contact with the exposed top surfaces of the through vias 104. The conductive features 108 may be formed using any suitable techniques such as deposition, damascene, dual damascene, or the like. The conductive features 108 may include a metal or a metal alloy such as copper, silver, gold, tungsten, cobalt, ruthenium, aluminum, alloys thereof, combinations thereof, or the like.

In some embodiments, the dielectric layers 110 are made of one or more suitable dielectric materials such as an oxide (e.g., silicon oxide), a nitride (e.g., silicon nitride), a polymer material, a polyimide material, a low-k dielectric material, a molding material (e.g., an EMC or the like), another dielectric material, or a combination thereof. The dielectric layers 110 may be formed by a process such as spin-coating, lamination, CVD, the like, or a combination thereof. However, any suitable dielectric materials and any suitable processes may be used. In some embodiments, the interconnect structure 106 have multiple dielectric layers 110, but the precise number of dielectric layers 110 may be dependent upon the design of the interconnect structure 106. Other elements, such as local silicon interconnects (LSIs) or the like that provide additional conductive routing, may also be formed in the interposer structure 10, although they are not shown in FIG. 1A.

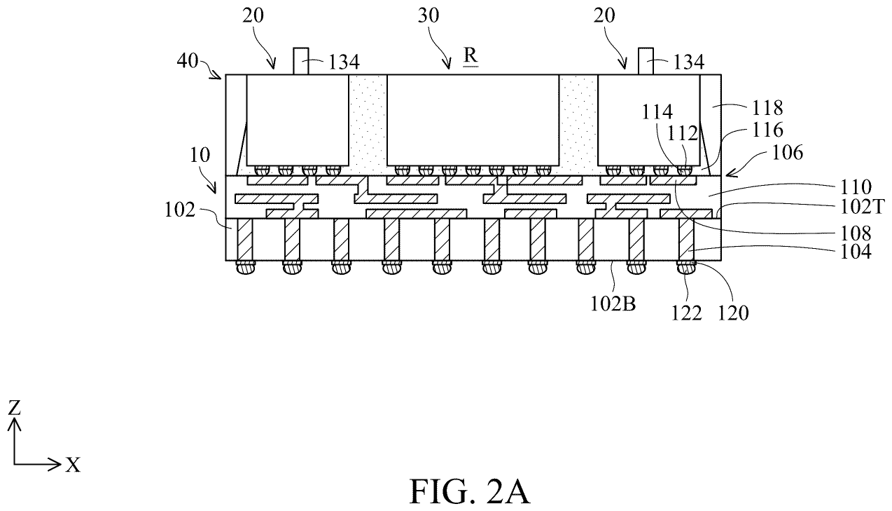

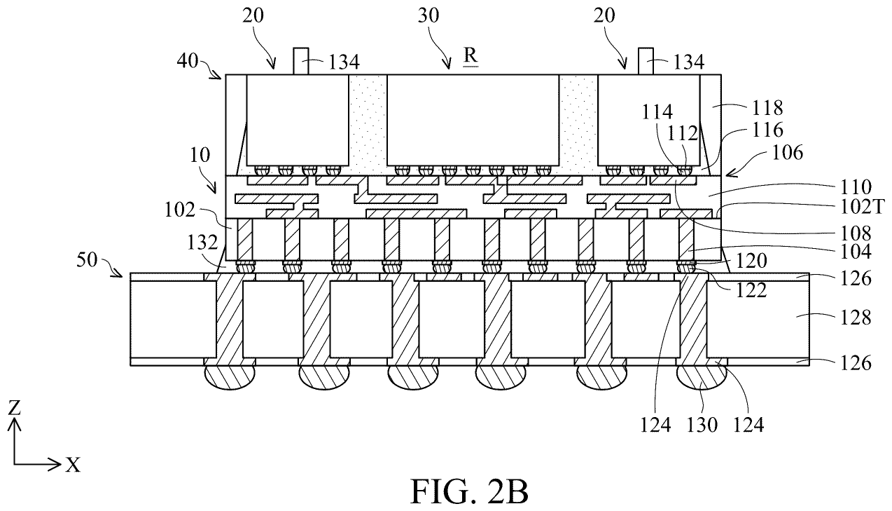

After the interconnect structure 106 is formed, semiconductor dies 20 and 30 are disposed over the interconnect structure 106, as shown in FIG. 1B in accordance with some embodiments. FIG. 1B-1 illustrates a first layout L₁ of the semiconductor dies 20 and 30 over the interconnect structure 106 in accordance with some embodiments. FIG. 1B-2 illustrates a second layout L₂ of the semiconductor dies 20 and 30 over the interconnect structure 106 in accordance with some embodiments. The structure shown in FIG. 1B is the cross-sectional view shown along line X_{1B}-X_{1B}′ in FIGS. 1B-1 and 1B-2 in accordance with some embodiments.

In some embodiments, the semiconductor dies 20 and 30 have different functions. For example, the semiconductor die 20 and/or 30 may be an integrated circuit die, a system-on-chip (SoC) device, a system-on-integrated-circuit (SoIC) device, a package, the like, or a combination thereof. In some embodiments, the semiconductor dies 20 and 30 include a logic die (e.g., central processing unit (CPU, xPU), graphics processing unit (GPU), a system-on-a-chip (SoC), an application processor (AP), microcontroller, etc.), a memory die (e.g., dynamic random access memory (DRAM) die, static random access memory (SRAM) die, a hybrid memory cube (HMC) die, a high bandwidth memory (HBM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), a BaseBand (BB) die, a photonic integrated circuit, a photonic package, a photonic die, the like, or combinations thereof.

In some embodiments, the semiconductor dies 20 include memory devices, such as a hybrid memory cube (HMC) module, a high bandwidth memory (HBM) module, or the like that includes multiple memory dies. In some embodiments, the semiconductor dies 30 include system on chip (SoC) dies, chip scale packages (CSP), or a combination thereof. In some embodiments, the semiconductor dies 20 are HBM dies and the semiconductor dies 30 are SoC dies. During the operation, heat will be generated by the semiconductor dies 20 and 30, and therefore the semiconductor dies 20 and 30 may be seen as the hot spots in the resulting package structure.

In some embodiments, one of the semiconductor dies 30 is sandwiched between two of the semiconductor dies 20 in the X direction, as shown in the top view in FIGS. 1B-1 and 1B-2. In some embodiments, one of the semiconductor dies 30 and two of the semiconductor dies 20 are aligned with each other in the X direction. In some embodiments, one of the semiconductor dies 20 is aligned with another one of the semiconductor dies 20 in the Y direction, as shown in FIG. 1B-1. In some embodiments, four of the semiconductor dies 20 are aligned with each other in the Y direction, as shown in FIG. 1B-2. In some embodiments, one of the semiconductor dies 30 is aligned with another one of the semiconductor die 30 in the Y direction, as shown in FIG. 1B-2.

In some embodiments, conductive pads 112 are formed over the semiconductor dies 20 and 30, and conductive connectors 114 are formed over the conductive pads 112 to electrically connect the semiconductor dies 20 and 30 and the interconnect structure 106. More specifically, the conductive pads 112 are electrically connected to the devices in the semiconductor dies 20 and 30 in accordance with some embodiments. In some embodiments, the conductive pads 112 are made of conductive material, such as W, Ru, Co, Cu, Ti, TiN, Ta, TaN, Mo, Ni, Al, other applicable conductive materials, or a combination thereof.

In some embodiments, the conductive connectors 114 are bonded to the conductive pads 112 of the semiconductor dies 20 and 30 and the conductive features 108 of the interconnect structure 106. More specifically, the semiconductor dies 20 and 30 are bonded to the interconnect structure 106 by aligning the conductive connectors 114 with corresponding conductive features 108 at the top of the interconnect structure 106. For example, the conductive features 108 of the interconnect structure 106 may be conductive pads, conductive pillars, solder bumps, or the like. The conductive connectors 114 are then placed into contact with the corresponding conductive features 108. Then, a reflow process may be performed to bond the conductive connectors 114 to the conductive features 108. In this manner, the semiconductor dies 20 and 30 may be physically and electrically connected to the interconnect structure 106.

In some embodiments, the conductive connectors 114 are solder balls, metal pillars, controlled collapse chip connection (C4) bumps, micro bumps, electroless nickel-electroless palladium-immersion gold technique (ENEPIG) formed bumps, or the like. In some embodiments, the conductive connectors 114 are micro bumps vertically sandwiched between the conductive pads 112 and conductive features 108. In some embodiments, the conductive connectors 114 are made of a conductive material such as solder, copper, aluminum, gold, nickel, silver, palladium, tin, the like, or a combination thereof. In some embodiments, the conductive connectors 114 are formed by initially forming a layer of solder through evaporation, electroplating, printing, solder transfer, ball placement, or the like, and a reflow process may be performed in order to shape the material into the desired bump shapes. In some embodiments, the conductive connectors 114 include metal pillars (such as a copper pillar) formed by sputtering, printing, electro plating, electroless plating, CVD, or the like. The metal pillars may be solder free and have substantially vertical sidewalls. In some other embodiments, the semiconductor dies 20 and 30 are bonded to the interconnect structure 106 using fusion bonding (not shown), such as dielectric-to-dielectric bonding and metal-to-metal bonding.

After the semiconductor dies 20 and 30 are bonded to the interconnect structure 106, an underfill 116 is formed around the semiconductor dies 20 and 30, as shown in FIG. 1C in accordance with some embodiments. The underfill 116 may reduce stress and protect the joints resulting from the reflowing of the conductive connectors 114. More specifically, bottom surfaces and the sidewalls of the semiconductor dies 20 and 30 are surrounded and covered by the underfill 116 in accordance with some embodiments. In addition, the conductive pads 112 and the conductive connectors 114 are embedded in the underfill 116 in accordance with some embodiments. In some embodiments, the top surfaces and the some portions of the sidewalls of the semiconductor dies 20 and 30 are not covered (i.e. are exposed) by the underfill 116.

In some embodiments, the underfill 116 are made of a polymer, epoxy, or the like. The underfill 116 may be formed by a capillary flow process after the semiconductor dies 20 and 30 are attached to the interconnect structure 106. After the underfill 116 is formed, a curing process may be performed. The curing process may include heating the underfill 116 to a predetermined temperature for a predetermined period of time, using an anneal process or other heating process. The curing process may also include an ultra-violet (UV) light exposure process, an infrared (IR) energy exposure process, combinations thereof, or a combination thereof with a heating process.

Next, a molding layer 118 is formed over the underfill 116, as shown in FIG. 1D in accordance with some embodiments. More specifically, the semiconductor dies 20 and 30 and the underfill 116 are covered and surrounded by the molding layer 118 in accordance with some embodiments.

The molding layer 118 may be a molding compound, an encapsulant, an epoxy, a polymer, a silicon oxide filler material, or the like. The molding layer 118 may be applied in liquid or semi-liquid form and then subsequently cured. The molding layer 118 may be molded using, for example, compressive molding, transfer molding, molded underfill (MUF), or other methods. A curing process may be performed to the molding layer 118. The curing process may include heating the molding layer 118 to a predetermined temperature for a predetermined period of time, using an anneal process or other heating process. The curing process may also include an ultra-violet (UV) light exposure process, an infrared (IR) energy exposure process, combinations thereof, or a combination thereof with a heating process.

In some embodiments, the molding layer 118 and the underfill 116 are made of different materials. In some embodiments, the molding layer 118 is also formed in the upper portions of the spaces between the semiconductor dies 20 and 30, although not shown in FIG. 1D. That is, an interface between the underfill 116 and the molding layer 118 may be lower than the top surfaces of the semiconductor dies 20 and 30. In some other embodiments, the underfill 116 is not formed, and the molding layer 118 is formed around the semiconductor dies 20 and 30 and between the semiconductor dies 20 and 30 and the interconnect structure 106.

After the molding layer 118 is formed, a planarization process is performed until the top surfaces of the semiconductor dies 20 and 30 are exposed, as shown in FIG. 1E in accordance with some embodiments. The planarization process may be performed to remove excess portions of molding layer 118 by using a mechanical grinding process, a chemical mechanical polishing (CMP) process, or the like. In some embodiments, the semiconductor dies 20 and 30 and/or the underfill 116 are also slightly polished during the planarization process. After the planarization process, the top surfaces of the semiconductor dies 20 and 30 are substantially level with the top surface of the molding layer 118 in accordance with some embodiments.

Afterwards, the substrate 102 is thinned from the second side 102B of the substrate 102, and conductive pads 120 and conductive connectors 122 are formed at the second side 102B of the substrate 102, as shown in FIG. 1F in accordance with some embodiments. More specifically, a carrier substrate (not shown) may be attached to the top surface of the semiconductor dies 20 and 30, and the second side 102B of the substrate 102 may be thinned until the bottom surfaces of the through vias 104 are exposed. Accordingly, the through vias 104 penetrate through the substrate 102 and may also be called as through-substrate vias 104. In some embodiments, the substrate 102 is thinned by performing a polishing process, such as a CMP process.

As shown in FIG. 1F, the interposer structure 10 includes the substrate 102, the through vias 104 formed through the substrate 102, and the interconnect structure 106 formed over the substrate 102, and the through vias 104 in the substrate 102 and the conductive features 108 of the interconnect structure 106 are electrically connected, so that the elements disposed at opposite sides of the interposer structure 10 may be electrically connected in accordance with some embodiments.

After the bottom surfaces of the through vias 104 are exposed, the conductive pads 120 are formed at the exposed bottom surfaces of the through vias 104, and the conductive connectors 122 are formed over the conductive pads 120, as shown in FIG. 1F in accordance with some embodiments. In some embodiments, the conductive pads 120 are made of conductive material, such as W, Ru, Co, Cu, Ti, TiN, Ta, TaN, Mo, Ni, Al, other applicable conductive materials, or a combination thereof. In some embodiments, the conductive connectors 122 are solder balls, metal pillars, controlled collapse chip connection (C4) bumps, micro bumps, electroless nickel-electroless palladium-immersion gold technique (ENEPIG) formed bumps, or the like. After the conductive connectors 122 are formed, the carrier substrate attached to the semiconductor dies 20 and 30 may be removed.

The structure shown in FIG. 1F may be called as a package component 40. Next, the package component 40 is disposed over a package substrate 50, as shown in FIG. 1G in accordance with some embodiments. The package component 40 may be physically and electrically connected to the package substrate 50 by the conductive connectors 122. In an embodiment, the package component 40 may be a chip-on-wafer-on-substrate (CoWoS) package or the like, although it should be appreciated that embodiments may be applied to other 3DIC packages.

The package substrate 50 may be any suitable substrate or component, such as a printed circuit board (PCB), a device die, a redistribution structure, an interposer, a wafer, a semiconductor substrate, a panel, a core substrate, a motherboard, a main board, or the like. In some embodiments, the package substrate 50 includes conductive features 124, such as conductive lines, conductive vias, conductive pads, or the like. In some embodiments, the conductive features 124 are in dielectric layers 126 and in a substrate 128 to make electrical interconnections within the package substrate 50 and to make electrical connections to the package component 40 or other components attached to the package substrate 50. The package substrate 50 may or may not comprise active devices and/or passive devices.

In some embodiments, conductive connectors 130 are formed on the conductive features 124 of the package substrate 50. In some embodiments, the conductive connectors 130 are solder balls, metal pillars, controlled collapse chip connection (C4) bumps, micro bumps, electroless nickel-electroless palladium-immersion gold technique (ENEPIG) formed bumps, or the like.

After the package component 40 is disposed on the package substrate 50, an underfill 132 is formed around the package component 40, as shown in FIG. 1G in accordance with some embodiments. More specifically, bottom surfaces and the lower sidewalls of the sidewalls of the package component 40 are surrounded and covered by the underfill 132 in accordance with some embodiments. In addition, the conductive pads 120 and the conductive connectors 122 are embedded in the underfill 132 in accordance with some embodiments.

In some embodiments, the underfill 132 are made of a polymer, epoxy, or the like. The underfill 132 may be formed by a capillary flow process after the package component 40 is attached to the package substrate 50. After the underfill 132 is formed, a curing process may be performed. The curing process may include heating the underfill 132 to a predetermined temperature for a predetermined period of time, using an anneal process or other heating process. The curing process may also include an ultra-violet (UV) light exposure process, an infrared (IR) energy exposure process, combinations thereof, or a combination thereof with a heating process.

Next, a protruding feature 134 is formed over the package component 40, as shown in FIG. 1H in accordance with some embodiments. The protruding feature 134 is configured to ensure a space for containing a liquid TIM (or flowable TIM) and to prevent the liquid TIM from flowing to other places.

In some embodiments, the protruding feature 134 is a single feature that continuously extending over the package component 40 to form an enclosed region in the top view. FIG. 1H-1 illustrates a protruding feature 134a formed over the package component 40 with the first layout L1 in accordance with some embodiments. FIG. 1H-2 illustrates the protruding feature 134a formed over the package component 40 with the second layout L2 in accordance with some embodiments.

The protruding feature 134a continuously extends over the top surfaces of the semiconductor dies 20 and 30 and a region Ra is surrounded by the protruding feature 134a in accordance with some embodiments. In some embodiments, the protruding feature 134a includes a first sidewall portion and a third sidewall portion extending in the X direction and a second sidewall portion and a fourth sidewall portion extending in the Y direction and connecting the first sidewall portion to the third sidewall portion. In some embodiments, the length L₁₃₄ₐ of the protruding feature 134a is smaller than 80% of the length L₄₀ of the package component 40, so there may be enough space for forming TIM surrounding the protruding feature 134 in subsequent process. Similarly, the width W₁₃₄ₐ of the protruding feature 134a is smaller than 80% of the width W₄₀ of the package component 40. In some embodiments, a thickness D₁₃₄ₐ of the protruding feature 134a is smaller than 20 μm, so that it will not take too much space over the package component 40.

In some embodiments, the first sidewall portion and the third sidewall portion individually extending over two of the semiconductor dies 20, and the second sidewall portion and the fourth sidewall portion individually extending over two of the semiconductor dies 20 and one of the semiconductor die 30, as shown in FIG. 1H-1. In some other embodiments, the first sidewall portion and the third sidewall portion individually extending over four of the semiconductor dies 20, and the second sidewall portion and the fourth sidewall portion individually extending over two of the semiconductor dies 20 and one of the semiconductor die 30, as shown in FIG. 1H-2.

In some other embodiments, the protruding feature 134 is include separated protruding units disposed over the package component 40, and these protruding units may also surrounds a central region in the top view. FIG. 1H-3 illustrates a protruding feature 134b formed over the package component 40 with the first layout L1 in accordance with some embodiments. FIG. 1H-4 illustrates the protruding feature 134b formed over the package component 40 with the second layout L2 in accordance with some embodiments.

As shown in FIGS. 1H-3 and 1H-4, the protruding feature 134b includes protruding units 134b_U over the semiconductor dies 20 and 30 and a region Rb is surrounded by the protruding feature 134b in accordance with some embodiments. In addition, the protruding units 134b_U are separated from each other.

In some embodiments, a first group of the protruding units 134b_U of the protruding feature 134b are aligned in the X direction, and a second group of the protruding units 134b_U of the protruding feature 134b are aligned in the X direction, and the first group of the protruding units 134b_U is spaced apart from the second group of the protruding units 134b_U in the Y direction. In some embodiments, the first group and the second group of the protruding units 134b_U are at a first side of the semiconductor die 30 in the top view. Similarly, a third group and a fourth group of the protruding units 134b_U of the protruding feature 134b are aligned in the X direction and spaced apart from each other in the Y direction. In some embodiments, the third group and the fourth group of the protruding units 134b_U are at a second side of the semiconductor die 30 in the top view. In some embodiments, a fifth group, a sixth group, a seventh group, and an eight group of the protruding units 134b_U of the protruding feature 134b are aligned in the Y direction and spaced apart from each other in the X direction. In some embodiments, the fifth group and the sixth group of the protruding units 134b_U are at a third side of the semiconductor die 30, and the seventh group and the eighth group of the protruding units 134b_U are at a fourth side of the semiconductor die 30 opposite to the third side in the top view. In some embodiments, a distance D₁ between two neighboring protruding units 134b_U in the same group is greater than 2 nm. In some embodiments, a distance D₂ between two protruding units 134b_U between two neighboring groups is smaller than 2 nm.

Furthermore, some of the protruding units 134b_U of the protruding feature 134b are completely within the projection area of one of the semiconductor dies 20 or 30 in accordance with some embodiments. Some of the protruding units 134b_U of the protruding feature 134b are partially overlaps one of the semiconductor dies 20 or 30 in accordance with some embodiments. Some of the protruding units 134b_U of the protruding feature 134b are partially overlaps two of the semiconductor dies 20 or 30 in accordance with some embodiments. Some of the protruding units 134b_U of the protruding feature 134b are partially overlaps one of the semiconductor dies 20 and one of the semiconductor dies 30 in accordance with some embodiments. In some embodiments, the length L_{134b} of the protruding feature 134b (e.g. measured from its outer edge) is smaller than 80% of the length L₄₀ of the package component 40, so there may be enough space for forming TIM surrounding the protruding feature 134b in subsequent process. Similarly, the width W_{134b} of the protruding feature 134b (e.g. measured from its outer edge) is smaller than 80% of the width W₄₀ of the package component 40 in accordance with some embodiments. In some embodiments, a thickness D_{134b} of the protruding units 134b_U of the protruding feature 134b is smaller than 20 μm, so that it will not took too much space over the package component 40.

The protruding feature 134, including the protruding features 134a and 134b, is made of Si in accordance with some embodiments. For example, a Si layer may be formed first and patterned to form the protruding feature 134. In some other embodiments, a sacrificial layer is formed with one or more openings, and the Si is formed in the one or more openings as the protruding feature 134, and the sacrificial layer is removed afterwards. In some embodiments, the protruding feature 134 is formed first and is attached to the package component 40 afterwards. In some other embodiments, the protruding feature 134 is formed over the package component 40.

Although the protruding feature 134 shown in FIG. 1H is attached to the package component 40 after the package component 40 is disposed over the package substrate 50, the protruding feature 134 may be formed before the package component 40 is disposed over the package substrate 50 (e.g. after the process shown in FIG. 1F is performed and before the process shown in FIG. 1G is performed.)

After the protruding feature 134 is attached to the package component 40, a thermal interface material (TIM) 136A and a TIM 136G are formed over the package component 40, as shown in FIG. 1I in accordance with some embodiments. FIG. 1I-1 illustrates a top view of the TIMs 136A and 136G around the protruding feature 134a over the package component 40 in accordance with some embodiments. FIG. 1I-2 illustrates a top view of the TIMs 136A and 136G around the protruding feature 134b over the package component 40 in accordance with some embodiments. The semiconductor dies 20 and 30 in package component 40 may have the layout shown in FIGS. 1H-1 to 1H-4, although they are not shown in FIGS. 1I-1 and 1I-2 for clarity.

More specifically, the TIM 136A is formed at the periphery region of the package component 40 in accordance with some embodiments. In some embodiments, the TIM 136A is spaced apart from the edges E40 of the package component 40, as shown in FIGS. 1I, 1I-1, and 1I-2. In some embodiments, a top surface of the TIM 136A is higher than a top surface of the protruding feature 134 at this stage. In some embodiments, the TIM 136A is a thermal adhesive. In some embodiments, the TIM 136A is made of a polymer. In some embodiments, the TIM 136A is a silicone adhesive tape.

The TIM 136G is formed in an area sandwiched between the TIM 136A and the protruding feature 134, as shown in FIGS. 1I, 1I-1, and 1I-2 in accordance with some embodiments. In some embodiments, a top surface of the TIM 136G is higher than a top surface of the protruding feature 134 at this stage. It should be noted that the TIM 136G shown in FIG. 1I is simplified for clarity, and the TIM 136G may be applied to the package component 40 with separated patterns shown in FIGS. 1I-1 and 1I-2. In some embodiments, the TIM 136G is a thermally conductive grease. In some embodiments, the TIM 136G is a silicone-based gel with thermal conductive particles suspended therein. In some embodiments, the thermal conductive particles includes metal, such as Ga, In, Sn, ZnO, or a combination thereof. In some embodiments, the TIM 136G includes more than 10% of Ga particles suspended in the silicone-based gel. In some embodiments, a thermal conductivity k_{136G} of the TIM 136G is no lower than about 6 W/mK. In some embodiments, a thermal conductivity k_{136G} of the TIM 136G is in a range of about 6 W/mK to about 9 W/mK.

Although both TIMs 136A and 136G may compensate for a coefficient of thermal expansion mismatch between the package component 40 and the lid attached afterwards, the TIMs 136A and 136G are made of different materials and have different functions. In some embodiments, a fluidity (flow mobility) of the TIM 136A is lower than a fluidity of the TIM 136G. Therefore, the TIM 136A formed at the periphery region of the package component 40 may help to prevent the leakage of the TIM formed therein. In addition, the TIM 136A may also provide additional mechanical strength to improve reliability over different thermal stresses. In some embodiments, a thermal conductivity of the TIM 136G is greater than a thermal conductivity of the TIM 136A. By using the TIM 136A at the periphery region and the TIM 136G in a region enclosed by the TIM 136A, the TIM 136G with a better thermal conductivity may be used without the consideration of the leakage due to its higher fluidity.

After the TIMs 136A and 136G are formed, a ring structure 138 is attached to the package substrate 50 by an adhesive 140, as shown in FIG. 1J in accordance with some embodiments. In some embodiments, the ring structure 138 is made of a material with a relatively low coefficient of thermal expansion. In some embodiments, the ring structure 138 is made of copper, copper alloy, copper tungsten (CuW), or aluminum-silicon-carbide (AlSiC), or other applicable materials. In some embodiments, the adhesive 140 is made of a polymer. In some embodiments, the adhesive 140 also has a relatively high thermal conductivity. In some embodiments, the adhesive 140 and the TIM 136A are made of a same material.

Next, a lid 142 is attached to the ring structure 138 through an adhesive 144 over the package component 40, as shown in FIG. 1K in accordance with some embodiments. As shown in FIG. 1K, the lid 142 includes a dam portion 142D and a bottom portion 142B under dam portion 142D, and one or more perforated holes 142H are formed through the bottom portion 142B of the lid 142 in accordance with some embodiments. The dam portion 142D and the bottom portion 142B together form a trench 142T, which can be used to contain an additional TIM afterwards. In some embodiments, a height H_{142D} of the dam portion 142D is in a range of about 10 μm to about 100 μm. The dam portion 142D may have enough height to contain the TIM applied afterwards. In addition, the reliability of the resulting device may decrease if the dam portion 142D does not have enough height.

In some embodiments, the protruding feature 134 is attached to (i.e. in direct contact to) the bottom surface of the bottom portion 142B of the lid 142. That is, a distance between the bottom surface of the bottom portion 142B of the lid 142 and a top surface of the package component 40 is substantially equal to a height of the protruding feature 134 in accordance with some embodiments. Accordingly, the TIM provided afterward may be confined in the region R by the protruding feature 134, the top surface of the package component 40, and the bottom surface of the lid 142 in accordance with some embodiments.

In addition, the TIMs 136A and 136G over the package component 40 are pressed by the bottom surface of the lid 142, so that the spaces therebetween is filled with the TIMs 136A and 136G, as shown in FIG. 1K in accordance with some embodiments. That is, although the TIMs 136A and 136G are higher than the protruding feature 134 when they are formed at the step shown in FIG. 1J, the height of the TIMs 136A and 136G become substantially equal to the height of the protruding feature 134, as shown in FIG. 1K in accordance with some embodiments.

In some embodiments, the space between the package component 40 and the bottom surface of the lid 142 outside the region surrounded by the protruding feature 134 is fully filled with the TIMs 136A and 136G. In some embodiments, the height of the TIM 136A and the height of the TIM 136G are substantially equal to the distance between the bottom surface of the bottom portion 142B of the lid 142 and the top surface of the package component 40. In some embodiments, the TIM 136A has a curved (e.g. rounded) sidewall. In some embodiments, a portion (e.g. the curved sidewall) of the TIM 136A laterally protrudes from a projection area of the package component 40. In some embodiments, a width of the TIM 136A in the X direction is smaller than a width of the TIM 136G in the X direction, as shown in FIG. 1K. However, in some other embodiments, a width of the TIM 136A in the X direction is greater than a width of the TIM 136G in the X direction (not shown).

In addition, the perforated holes 142H penetrate through the bottom portion 142B of the lid 142, so that the additional TIM may be applied to the region R under the bottom portion 142B through the perforated holes 142H. In some embodiments, a diameter of the perforated hole 142H is in a range from about 3.1 mm to about 5 mm. The perforated hole 142H may have a suitable size for applying the TIM afterwards.

The perforated holes 142H in the lid 142 may have different arrangements, as long as they are inside the projection area of the region R surrounded by the protruding feature 134 in the top view. FIG. 1K-1 illustrates a top view of a lid 142a with the perforated holes 142H over the protruding feature 134a in accordance with some embodiments. FIG. 1K-2 illustrates a top view of the lid 142a with the perforated holes 142H over the protruding feature 134b in accordance with some embodiments. FIG. 1K-3 illustrates a top view of a lid 142b with the perforated hole 142H over the protruding feature 134a in accordance with some embodiments. FIG. 1K-4 illustrates a top view of the lid 142b with the perforated hole 142H over the protruding feature 134b in accordance with some embodiments.

More specifically, the lid 142a includes four perforated holes 142H in the bottom portion 142B. As shown in FIG. 1K-1, the perforated holes 142H of the lid 142a are located in the region Ra surrounded by the protruding feature 134a in the top view in accordance with some embodiments. In addition, the perforated holes 142H are position at four corners of the region Ra in accordance with some embodiments. Similarly, in FIG. 1K-2, the perforated holes 142H of the lid 142a are located in the region Rb surrounded by the protruding feature 134b in the top view in accordance with some embodiments. In addition, the perforated holes 142H are position at four corners of the region Rb in accordance with some embodiments.

In some other embodiments, the lid 142b includes a single perforated hole 142H in the bottom portion 142B. That is, although the lid 142 shown in FIG. 1K has more than one perforated holes 142H, the lid 142 may have a single perforated hole 142H. As shown in FIG. 1K-3, the perforated hole 142H of the lid 142a is located in the region Ra surrounded by the protruding feature 134a in the top view in accordance with some embodiments. In addition, the perforated hole 142H is position at the central point of the region Ra in accordance with some embodiments. Similarly, in FIG. 1K-4, the perforated hole 142H of the lid 142b is located in the region Rb surrounded by the protruding feature 134b in the top view in accordance with some embodiments. In addition, the perforated hole 142H is position at a central point of the region Rb in accordance with some embodiments.

The lid 142, including the lid 142a and 142b, is made of material with a high thermal conductivity, for example, between about 200 W/mK to about 400 W/mK. In some embodiments, the lid 142 is made of copper (Cu), copper alloy, copper tungsten (CuW), aluminum-silicon-carbide (AlSiC), or other applicable materials. In addition, the perforated holes 124H are formed by drilling through the bottom portion 142B in accordance with some embodiments. In some embodiments, the adhesive 144 and the adhesive 140 are made of a same material. In some embodiments, the adhesives 140 and 144 and the TIM 136A are made of a same material.

After the lid 142 is attached to the ring structure 138, a TIM 136L is applied to the lid 142, as shown in FIG. 1L in accordance with some embodiments. More specifically, the region R surrounded by the protruding feature 134, the trench 142T surrounded by the dam portions 142D, and the perforated holes 142H are all filled with the TIM 136L in accordance with some embodiments.

In some embodiments, the TIM 136L is made of a metal that is at a liquid form at room temperature. The TIM 136L may be a liquid metal with a high thermal conductivity, so that the heat passivation of the resulting package structure may be highly improved. In some embodiments, a thermal conductivity k_{136L} of the TIM 136L is in a range of about 70 W/mK to about 80 W/mK. On the other hand, since the TIM 136L is in the liquid form during operation, it needs to be properly sealed to prevent it from leaking. Therefore, in these embodiments, the TIM 136L is confined to the regions surrounded by the lid 142 and the protruding feature 134, and the protruding feature 134 is further surrounded by the TIMs 136G and 136A, so that the overflow issue due to the high fluidity can be prevented. In some embodiments, the TIM 136L is a gallium-based material, such as gallium or an alloy of gallium and a metal consisting of a group selected from indium, tin, bismuth, nickel, and aluminum.

In some embodiments, a fluidity of the TIM 136L is higher than a fluidity of the TIM 136G, and the fluidity of the TIM 136G is higher than a fluidity of the TIM 136A. In addition, a thermal conductivity of the TIM 136L is greater than a thermal conductivity of the TIM 136G, and the thermal conductivity of the TIM 136G is greater than a thermal conductivity of the TIM 136A. By using the TIM 136A with lower fluidity at the periphery region and the TIM 136L with high thermal conductivity over the central region of the package component 40 (e.g. the hot spots of the device), the heat dissipation may be improved without the risk of leakage. In addition, the TIM 136G sandwiched between the TIM 136A and TIM 136L may be used as a buffer region to prevent the leakage of the TIM 136L while still have a relatively high thermal conductivity.

FIGS. 1L-1 to 1L-5 illustrate examples of applying the TIM 136L to the lid 142 in accordance with some embodiments. FIG. 1L-1 illustrates that the TIM 136L is applied to the region R by applying the TIM 136L through one of the perforated holes 142H in accordance with some embodiments. More specifically, an applying tool 146 is used to apply the TIM 136L through one of the perforated holes 142H until the region R surrounded by the protruding feature 134 under the lid 142a is fully filled in accordance with some embodiments. Afterwards, the perforate holes 142H and the trench 142T are filled with the TIM 136L, as shown in FIG. 1L in accordance with some embodiments.

FIG. 1L-2 illustrates that the TIM 136L is applied to the region R by applying the TIM 136L through all of the perforated holes 142H in accordance with some embodiments. More specifically, the applying tools 146 are used to apply the TIM 136L through all of the perforated holes 142H until the region R surrounded by the protruding feature 134 under the lid 142a and all the perforate holes 142H are fully filled in accordance with some embodiments. Afterwards, the trench 142T are filled with the TIM 136L, as shown in FIG. 1L in accordance with some embodiments. By applying the TIM 136L through all of the perforate holes 142H, the TIM 136L may be applied to the lid 142a more efficiently.

FIG. 1L-3 illustrates that the TIM 136L is applied to the region R by applying the TIM 136L through the perforated hole 142H in the central region of the lid 142b in accordance with some embodiments. More specifically, the applying tool 146 is used to apply the TIM 136L through the perforated hole 142H until the region R surrounded by the protruding feature 134 under the lid 142b and the perforate hole 142H is fully filled in accordance with some embodiments. Afterwards, the trench 142T are filled with the TIM 136L, as shown in FIG. 1L in accordance with some embodiments.

FIGS. 1L-4 and 1L-5 illustrate that the TIM 136L is applied to the region R by applying the TIM 136L to the trench 142T in accordance with some embodiments. More specifically, the applying tool 146 is used to apply the TIM 136L in the trench 142T, and the TIM 136L flows into the region R through perforate holes 142H of the lid 142a, as shown in FIG. 1L-4 in accordance with some embodiments. Similarly, the applying tool 146 is used to apply the TIM 136L in the trench 142T, and the TIM 136L flows into the region R through the perforate hole 142H of the lid 142b, as shown in FIG. 1L-5 in accordance with some embodiments. The process continuous until the region R, the perforate holes 142H and the trench 142T are fully filled with the TIM, as shown in FIG. 1L in accordance with some embodiments.

After the TIM 136L is applied to the lid 142, an external cooling tool 148 is attached to the lid 142 to form the package structure 100, as shown in FIG. 1M in accordance with some embodiments. More specifically, the external cooling tool 148 may be physically and thermally connected to the lid 142 and be configured to dissipate the heat from the package component 40 to the external environment. In addition, the TIM 136L is now confined in a space that is enclosed by the external cooling tool 148, the lid 142, the protruding feature 134, and the package component 40 in accordance with some embodiments.

In some embodiments, the external cooling tool 148 includes fins for radiative heat dissipation to the surrounding environment. In some embodiments, the external cooling tool 148 includes a heat sink, a heat pipe, a vapor chamber, a liquid cooling system, an air cooling system, a two-phase cooling system, a thermoelectric cooling system, a cooling fan, a heat spreader, the like, or a combination thereof. In some embodiments, the size of external cooling tool 148 is greater than the size of the lid 142.

The resulting package structure 100 may be an advance package device that may have relatively high power consumption and may generate heat, especially over the semiconductor dies 20 and 30, and the TIMs 136L, 136G, and 136A may help to passivate the heat to the external cooling tool 148 more efficiently during operation. In addition, after operating for a certain of time, the TIM 136L may be replaced by a new TIM, so that the efficiency of the heat dissipation may remain even after a period of time.

More specifically, after the package structure is operated for a period of time, the external cooling tool 148 is removed to expose the TIM 136L, as shown in FIG. 1N in accordance with some embodiments. Afterwards, the used TIM 136L is removed, as shown in FIG. 1O in accordance with some embodiments. Since the TIM 136L is a liquid, the TIM 136L in the lid 142 can be poured out from the package structure 100 in accordance with some embodiments. In some other embodiments, the TIM 136L is removed using a suction nozzle. For example, the TIM 136L in the region R may be suck out through perforated holes 142H by a suction nozzle.

Next, a new TIM 136L′ is applied to the lid 142, as shown in FIG. 1P in accordance with some embodiments. The TIM 136L′ may be the same or different from the TIM 136L applied previously. In some embodiments, the TIM 136L′ is a gallium-based material, such as gallium or an alloy of gallium and a metal consisting of a group selected from indium, tin, bismuth, nickel, and aluminum. Afterwards, the external cooling tool 148 is attached to the lid 142 again to form a renewed package structure 100′, as shown in FIG. 1Q in accordance with some embodiments. Since the used TIM 136L was replaced by the TIM 136L′, the renewed package structure 100′ may have improved performance.

As shown in FIG. 1Q, the package structure 100 includes the package component 40, the protruding feature 134 attached to the package component 40, and the lid 142 disposed over the package component 40 and the protruding feature 134 in accordance with some embodiments. In addition, the package component 40 includes the semiconductor dies 20 and 30 disposed over the interposer structure 10 in accordance with some embodiments.

In some embodiments, the package structure 100 further includes the TIMs 136A, 136G, and 136L under the bottom surface of the lid 142. The TIMs 136A and 136G are located and at a first side of the protruding feature 134, and the TIM 136L (or 136L′) is located at a second side of the protruding feature 134 in accordance with some embodiments. In some embodiments, the TIM 136G is laterally sandwiched between the protruding feature 134 and the TIM 136A.

In some embodiments, the TIM 136L includes a first portion in the range R surrounded by the protruding feature 134 in the top view and is under the bottom surface of the lid 142. In some embodiments, the TIM 136L further includes a second portion in the trench 142T of the lid that is over the bottom portion 142B and surrounded by the dam portion 142D.

In some embodiments, the TIM 136L further includes a third portion formed in the perforated hole 142H that penetrates through the bottom portion 142B of the lid 142. In addition, the third portion of the TIM 136L connects with the first portion and the second portion of the TIM 136L, as shown in FIG. 1Q in accordance with some embodiments.

The sequence of the steps described above can be changed. FIGS. 2A and 2B illustrate cross-sectional views of some of the intermediate stages of manufacturing the package structure 100 in accordance with some other embodiments. More specifically, the processes shown in FIGS. 1A to 1F and described above may be performed to form the package component 40, and the protruding feature 134 is attached to the package component 40, as shown in FIG. 2A in accordance with some embodiments. After the protruding feature 134 is formed, the package component 40 is then attached to the package substrate 50, as shown in FIG. 2B in accordance with some embodiments. Next, the processes shown in FIGS. 1I to 1Q and described above may be performed to form the package structure 100 as shown in FIG. 1Q.

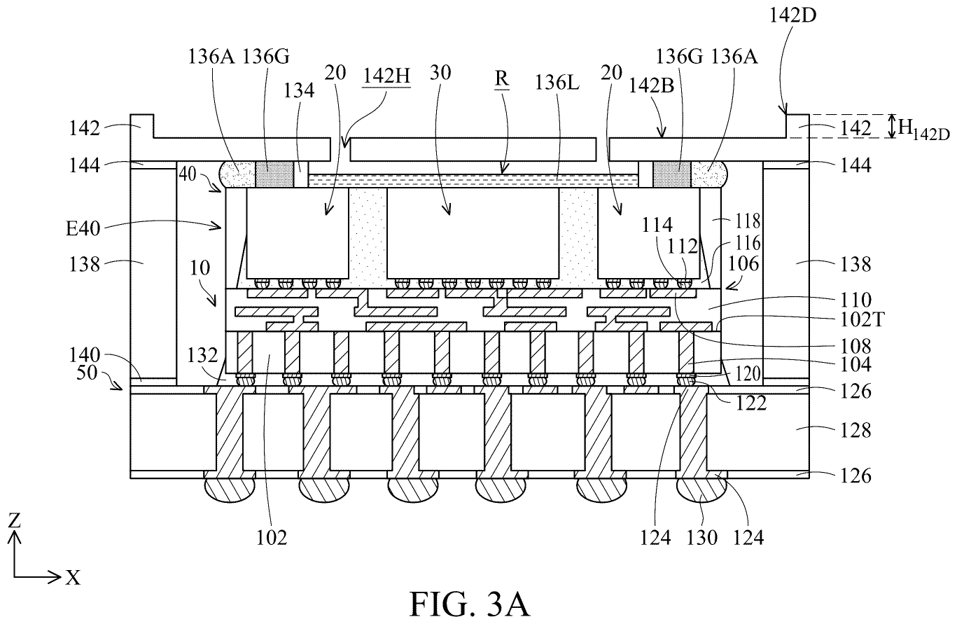

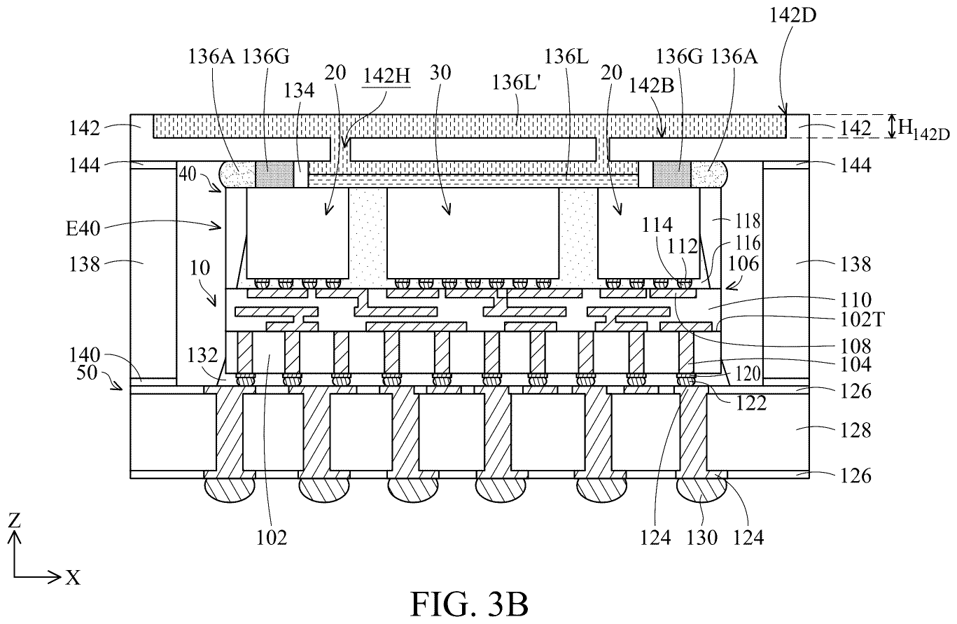

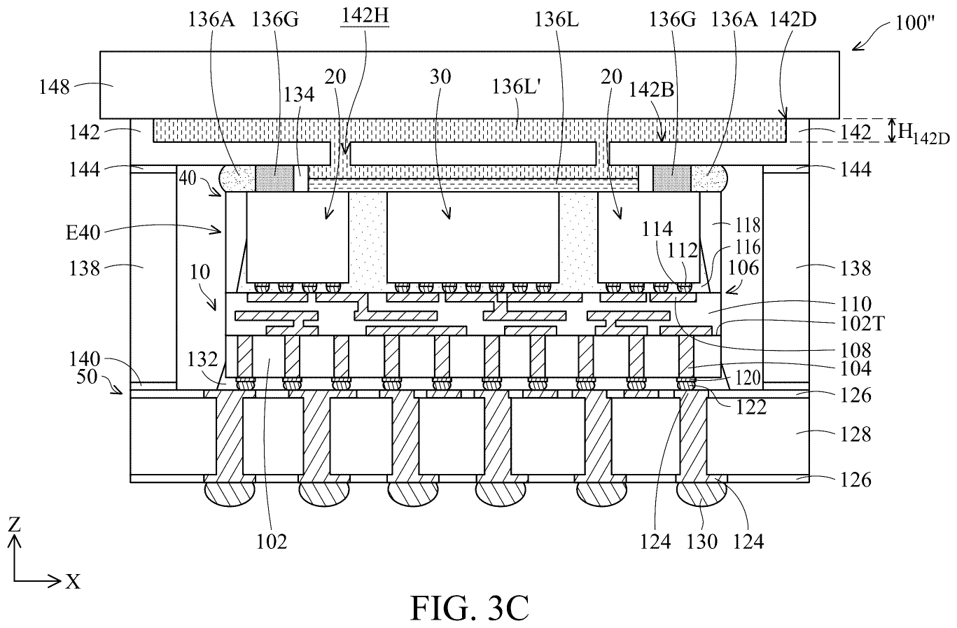

FIGS. 3A to 3C illustrate cross-sectional views of intermediate stages of manufacturing a package structure 100″ in accordance with some embodiments. The package structure 100″ may be similar to the package structure 100′ described previously, except the used TIM 136L is not completely replaced by the new TIM 136L′ in accordance with some embodiments. Other processes and materials for forming the package structure 100″ may be similar to, or the same as, those for forming the package structure 100 described previously and are not repeated herein.

More specifically, the processes shown in FIGS. 1A to 1M are performed to form the package structure 100, and the external cooling tool 148 is detached and the used TIM 136L is partially removed from the lid 142, as shown in FIG. 3A in accordance with some embodiments. That is, some of the used TIM 136L still remain in the region R surrounded by the protruding feature 134 at this stage in accordance with some embodiments.

After the TIM 136L is partially removed, the TIM 136L′ is filled in the range R over the TIM 136L, as shown in FIG. 3B in accordance with some embodiments. Next, the external cooling tool 148 is attached to the lid 142 to form the package structure 100″, as shown in FIG. 3C in accordance with some embodiments. In some embodiments, the TIM 136L and the TIM 136L′ are made of different materials, and therefore the range R surrounded by the protruding feature 134 includes two kinds of TIMs.

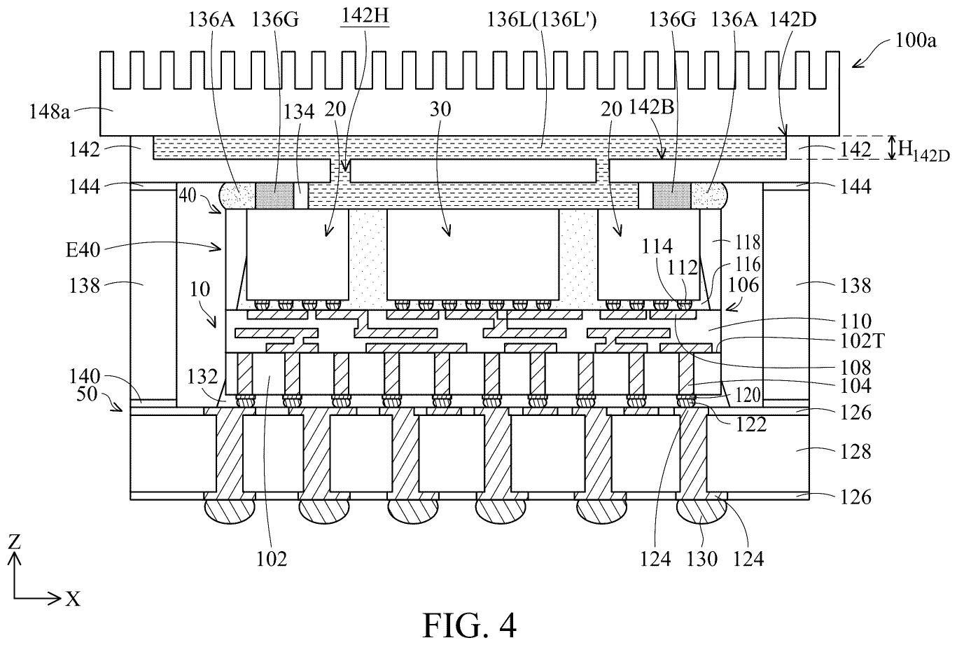

FIG. 4 illustrates a cross-sectional view of a package structure 100a in accordance with some embodiments. The package structure 100a may be similar to the package structures 100 and 100′ described previously, except the external cooling tool 148 is a heat sink 148a with cooling fins in accordance with some embodiments. As shown in FIG. 4, the TIM 136L (or 136L′) is covered by the heat sink 148a. Processes and materials for forming the package structure 100a may be similar to, or the same as, those for forming the package structures 100 and 100′ described previously and are not repeated herein.

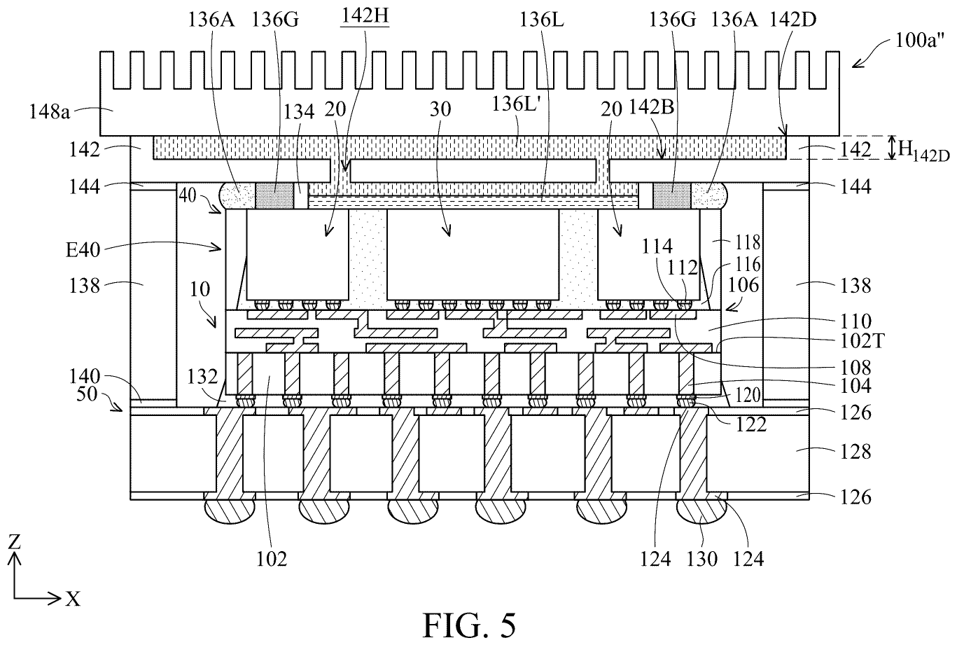

FIG. 5 illustrates a cross-sectional view of a package structure 100a″ in accordance with some embodiments. The package structure 100a″ may be similar to the package structure 100″ described previously, except the external cooling tool 148 is a heat sink 148a with cooling fins in accordance with some embodiments. Processes and materials for forming the package structure 100a″ may be similar to, or the same as, those for forming the package structures 100″ and 100a described previously and are not repeated herein.

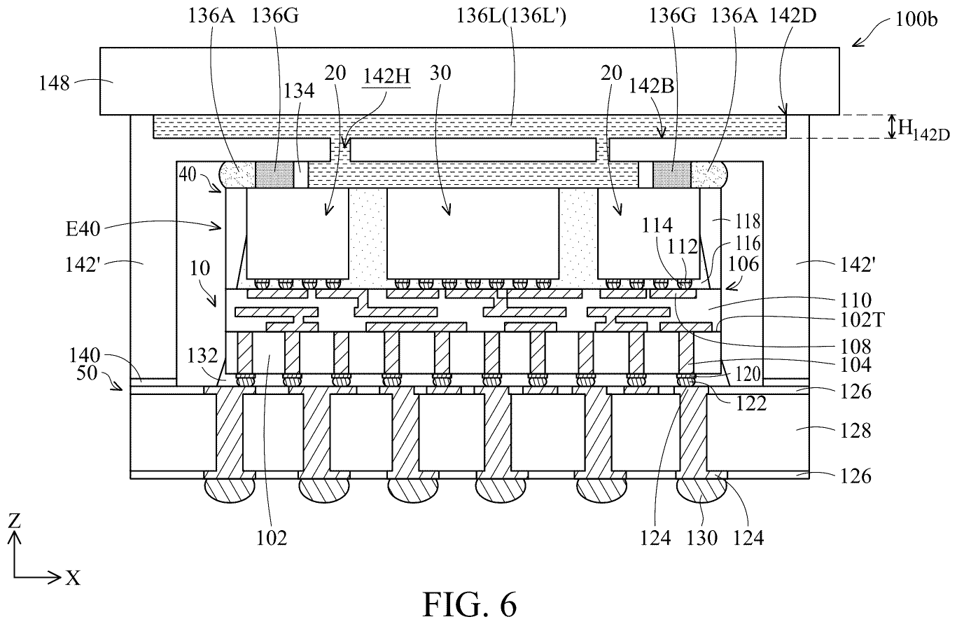

FIG. 6 illustrates a cross-sectional view of a package structure 100b in accordance with some embodiments. The package structure 100b may be similar to the package structures 100 and 100′ described previously, except a lid 142′ is used to replace the lid 142 and the ring structure 138 in accordance with some embodiments. Processes and materials for forming the package structure 100b may be similar to, or the same as, those for forming the package structures 100 and 100′ described previously and are not repeated herein.

More specifically, the lid 142′ further includes an extending portion at the edge of the lid 142′ that can be attached to the package substrate 50, and therefore the ring structure 138 can be replaced by the extending portion in accordance with some embodiments. In some embodiments, the extending portion of the lid 142′ and the dam portion 142D and the bottom portion 142B are made of the same material. In addition, the dam portion 142D and the bottom portion 142B of the lid 142′ may be the same as those of the lid 142 described previously and therefore are not repeated herein. As shown in FIG. 6, the TIM 136L (or 136L′) is covered by the lid 142′ in accordance with some embodiments.

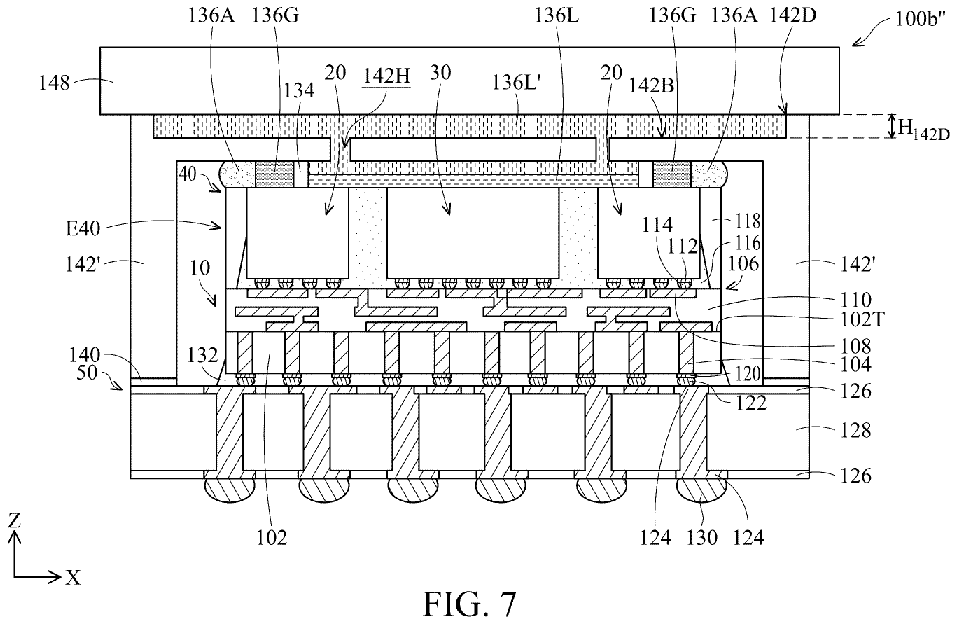

FIG. 7 illustrates a cross-sectional view of a package structure 100b″ in accordance with some embodiments. The package structure 100b″ may be similar to the package structure 100″ described previously, except the lid 142′ is used to replace the lid 142 and the ring structure 138 in accordance with some embodiments. Processes and materials for forming the package structure 100b″ may be similar to, or the same as, those for forming the package structures 100″ and 100b described previously and are not repeated herein.

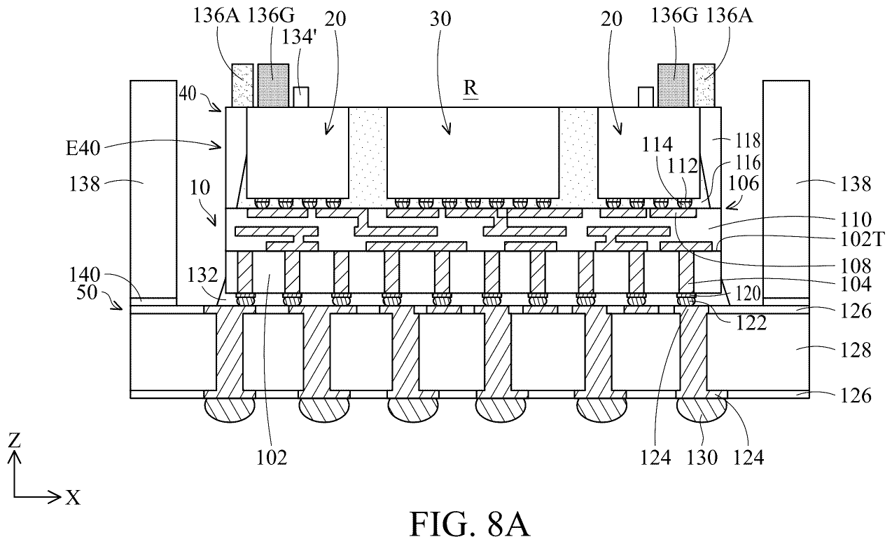

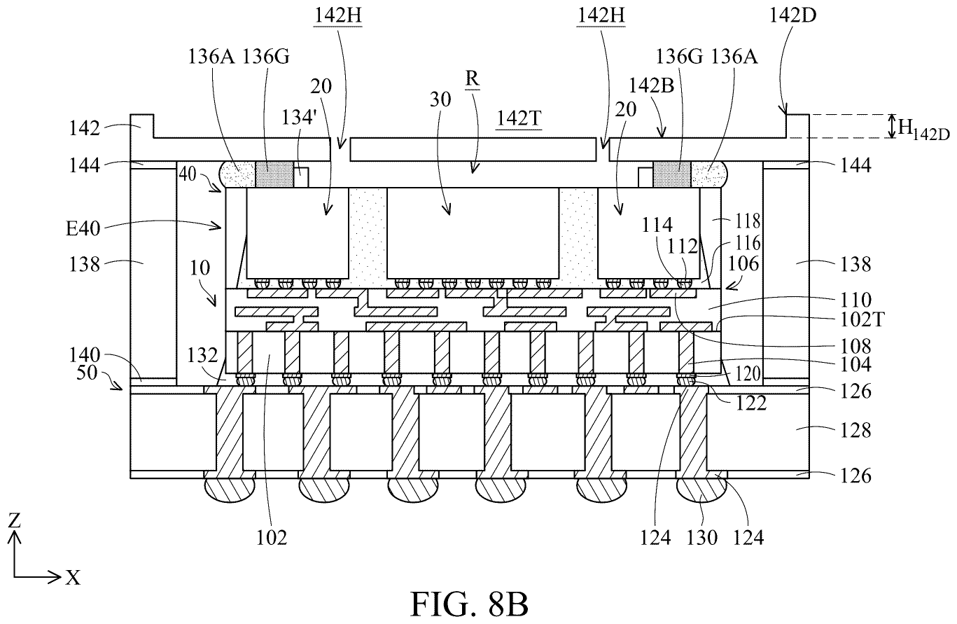

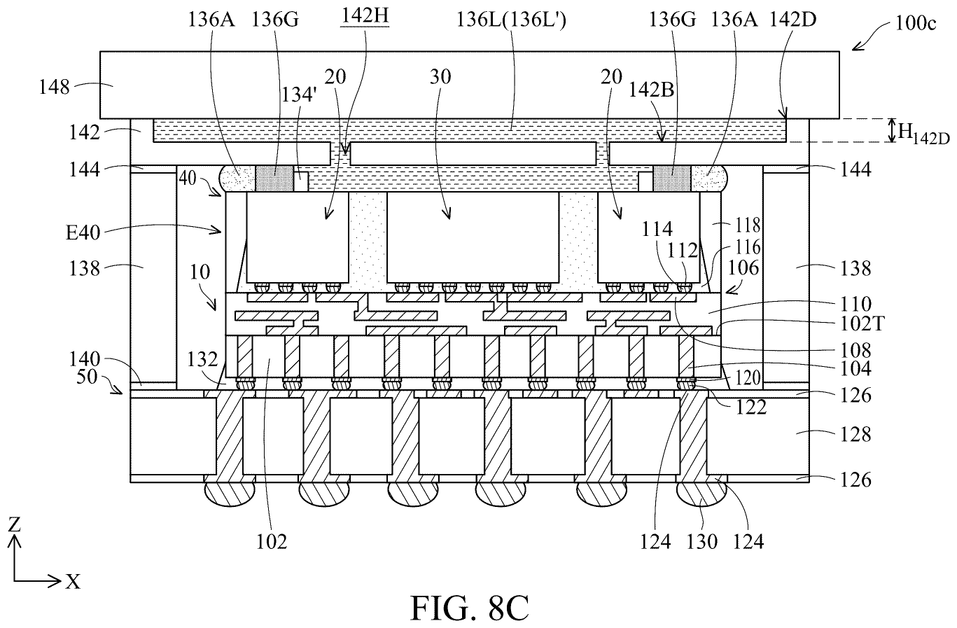

FIGS. 8A to 8C illustrate cross-sectional views of intermediate stages of manufacturing a package structure 100c in accordance with some embodiments. The package structure 100c may be similar to the package structures 100 and 100′ described previously, except its protruding feature 134′ is not in contact with the lid 142 in accordance with some embodiments. Other processes and materials for forming the package structure 100c may be similar to, or the same as, those for forming the package structures 100 and 100′ described previously and are not repeated herein.

More specifically, the processes shown in FIGS. 1A to 1I are performed, and the ring structure 138 is attached to the package substrate 50, as shown in FIG. 8A in accordance with some embodiments. In some embodiments, a top surface of the protruding feature 134′ is lower than a top surface of the ring structure 138.

Next, the lid 142 is attached to the ring structure 138, as shown in FIG. 8B in accordance with some embodiments. Similar to the structure shown in FIG. 1K, the TIMs 136A and 136G over the package component 40 are pressed by the bottom surface of the lid 142, so that the spaces between the lid 142 and the package component 40 is filled with the TIMs 136A and 136G in accordance with some embodiments. More specifically, the space between the package component 40 and the bottom surface of the lid 142 outside the region surrounded by the protruding feature 134′ is fully filled with the TIMs 136A and 136G in accordance with some embodiments. However, since the protruding feature 134′ has a relatively smaller height, the height of the TIMs 136A and 136G is still higher than the height of the protruding feature 134′ even after the lid 142 is attached to the ring structure 138 in accordance with some embodiments.

As shown in FIG. 8B, a gap exists between the top surface of the protruding feature 134′ and the bottom surface of the lid 142 in accordance with some embodiments. In some embodiments, the height of the TIM 136A and the height of the TIM 136G are substantially equal to the distance between the bottom surface of the bottom portion 142B of the lid 142 and the top surface of the package component 40 and is greater than the height of the protruding feature 134′.

Afterwards, the processes shown in FIGS. 1L to 1Q are performed to form the package structure 100c, as shown in FIG. 8C in accordance with some embodiments. The gap between the top surface of the protruding feature 134′ and the bottom surface of the lid 142 is filled by the TIM 136L (or 136L′), as shown in FIG. 8C in accordance with some embodiments. That is, the top surface of the protruding feature 134′ is covered by the TIM 136L. In addition, the TIM 136L is in contact with the TIM 136G, and therefore there is an interface between the TIM 136L and the TIM 136G in accordance with some embodiments. In some embodiments, the interface between the TIM 136L and the TIM 136G is substantially aligned with an outer sidewall of the protruding feature 134′.

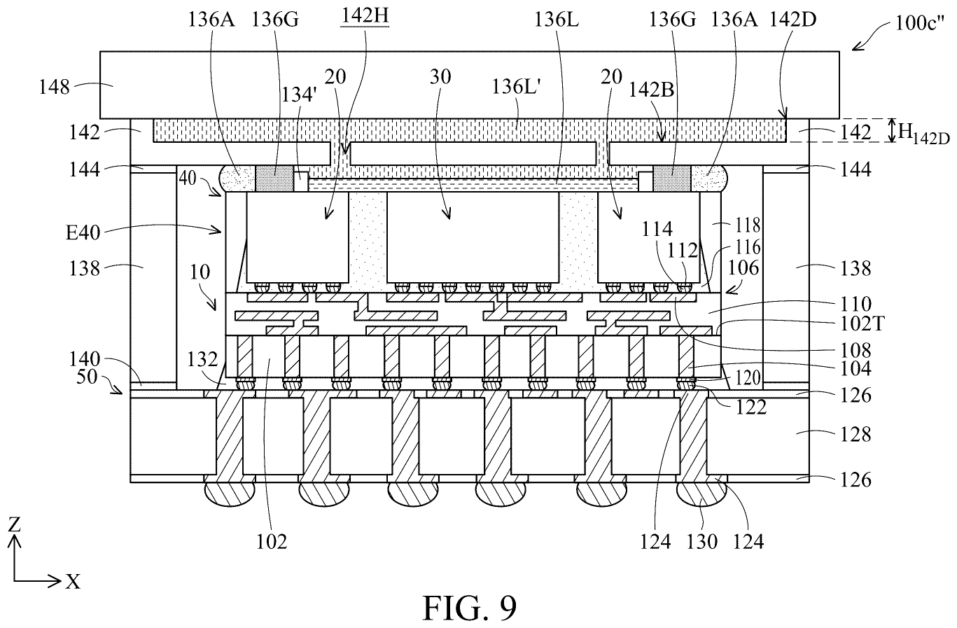

FIG. 9 illustrates a cross-sectional view of a package structure 100c″ in accordance with some embodiments. The package structure 100c″ may be similar to the package structure 100c described previously, except the processes shown in FIGS. 3A to 3C are applied in accordance with some embodiments. That is, the region R includes both the TIMs 136L and 136L′ in accordance with some embodiments. Other processes and materials for forming the package structure 100c″ may be similar to, or the same as, those for forming the package structure 100c described previously and are not repeated herein.

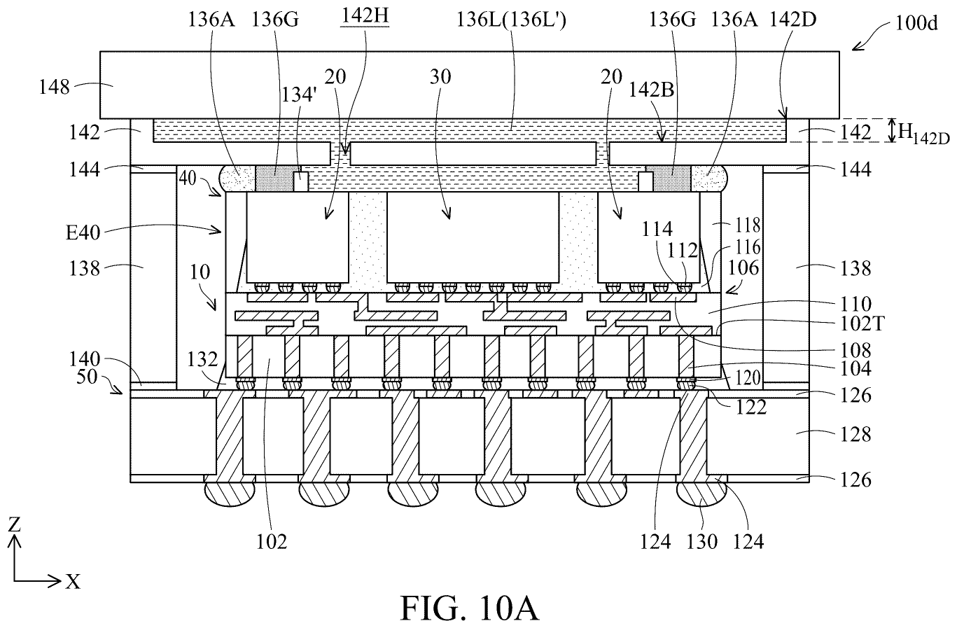

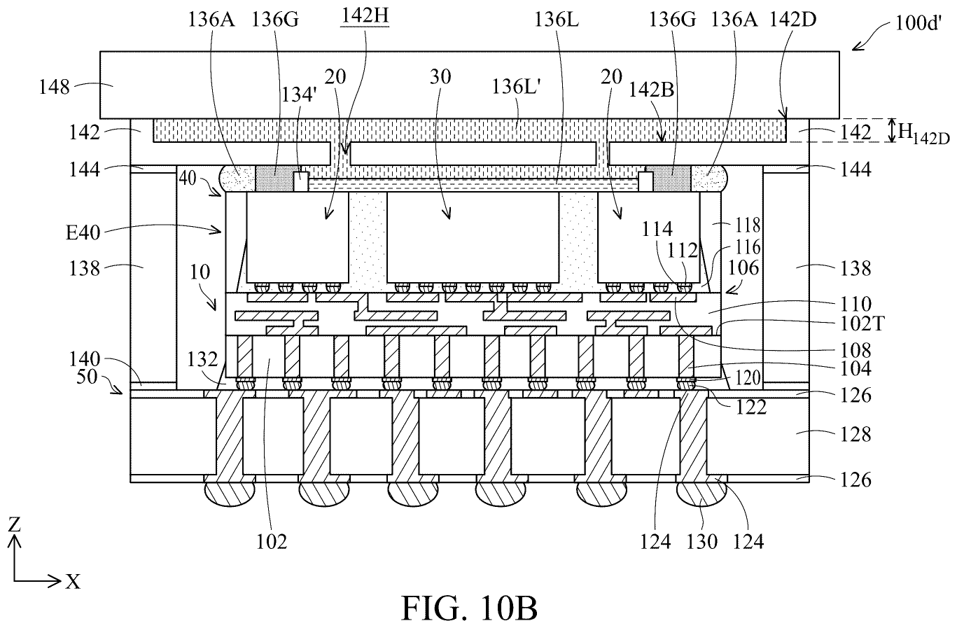

FIG. 10A illustrates a cross-sectional view of a package structure 100d in accordance with some embodiments. The package structure 100d may be similar to the package structure 100c described previously, except the top surface of the protruding feature 134′ are covered by both the TIMs 136G and 136L (or 136L′) in accordance with some embodiments. More specifically, the top surface of the protruding feature 134a is partially covered by the TIM 136G and partially covered by the TIM 136L in accordance with some embodiments. In some embodiments, the interface between the TIM 136G and the TIM 136L is over the top surface of the protruding feature 134′. Other processes and materials for forming the package structure 100d may be similar to, or the same as, those for forming the package structure 100c described previously and are not repeated herein.

FIG. 10B illustrates a cross-sectional view of a package structure 100d″ in accordance with some embodiments. The package structure 100d″ may be similar to the package structure 100d described previously, except the processes shown in FIGS. 3A to 3C are applied in accordance with some embodiments. That is, the region R includes both the TIMs 136L and 136L′ in accordance with some embodiments. Other processes and materials for forming the package structure 100d″ may be similar to, or the same as, those for forming the package structure 100d described previously and are not repeated herein.

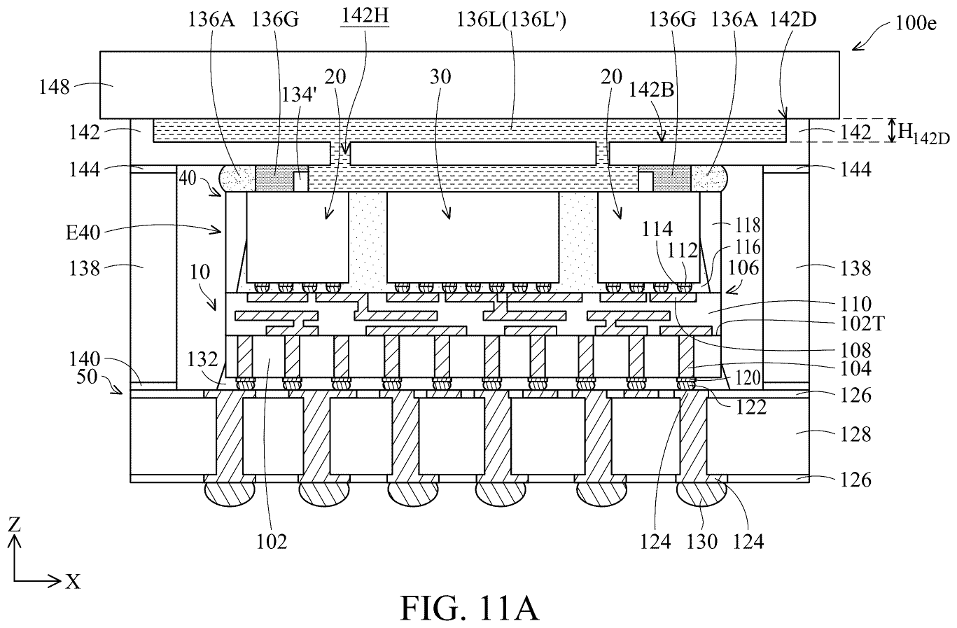

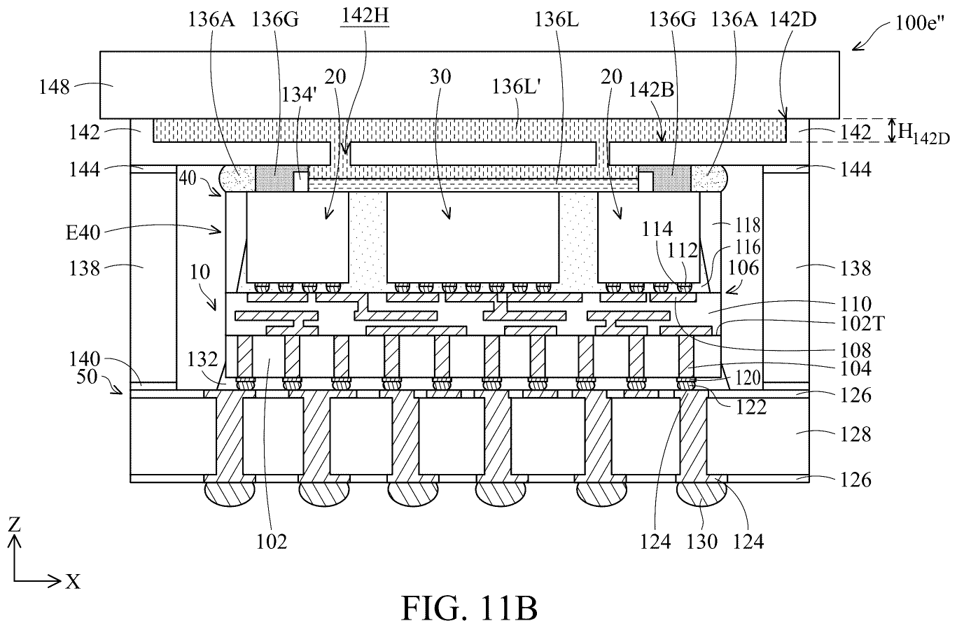

FIG. 11A illustrates a cross-sectional view of a package structure 100e in accordance with some embodiments. The package structure 100e may be similar to the package structure 100c described previously, except the top surface of the protruding feature 134′ are covered by the TIM 136G in accordance with some embodiments. More specifically, the gap between the top surface of the protruding feature 134′ and the bottom surface of the lid 142 is filled by the TIM 136G in accordance with some embodiments. That is, the top surface of the protruding feature 134′ is covered by the TIM 136G. In some embodiments, the interface between the TIM 136L and the TIM 136G is substantially aligned with an inner sidewall of the protruding feature 134′. Other processes and materials for forming the package structure 100e may be similar to, or the same as, those for forming the package structure 100c described previously and are not repeated herein.

FIG. 11B illustrates a cross-sectional view of a package structure 100e″ in accordance with some embodiments. The package structure 100e″ may be similar to the package structure 100e described previously, except the processes shown in FIGS. 3A to 3C are applied in accordance with some embodiments. That is, the region R includes both the TIMs 136L and 136L′ in accordance with some embodiments. Other processes and materials for forming the package structure 100e″ may be similar to, or the same as, those for forming the package structure 100e described previously and are not repeated herein.

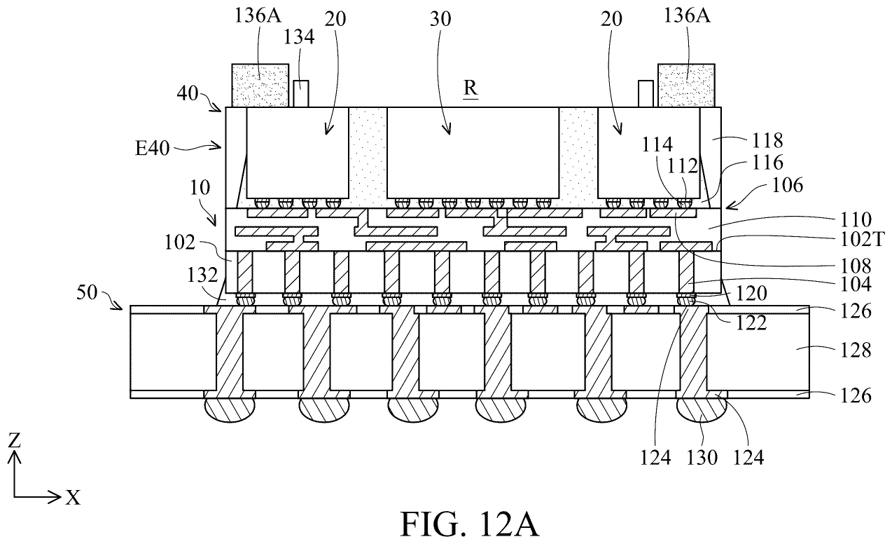

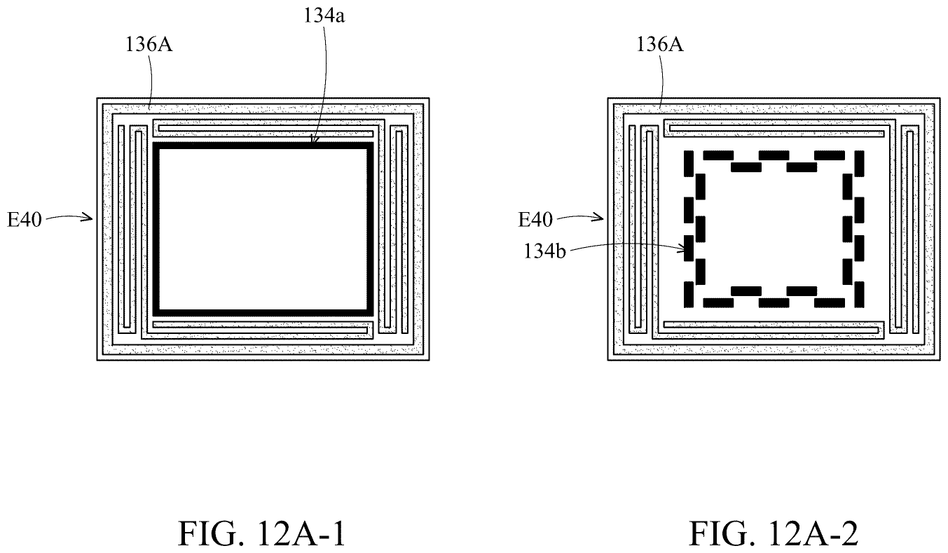

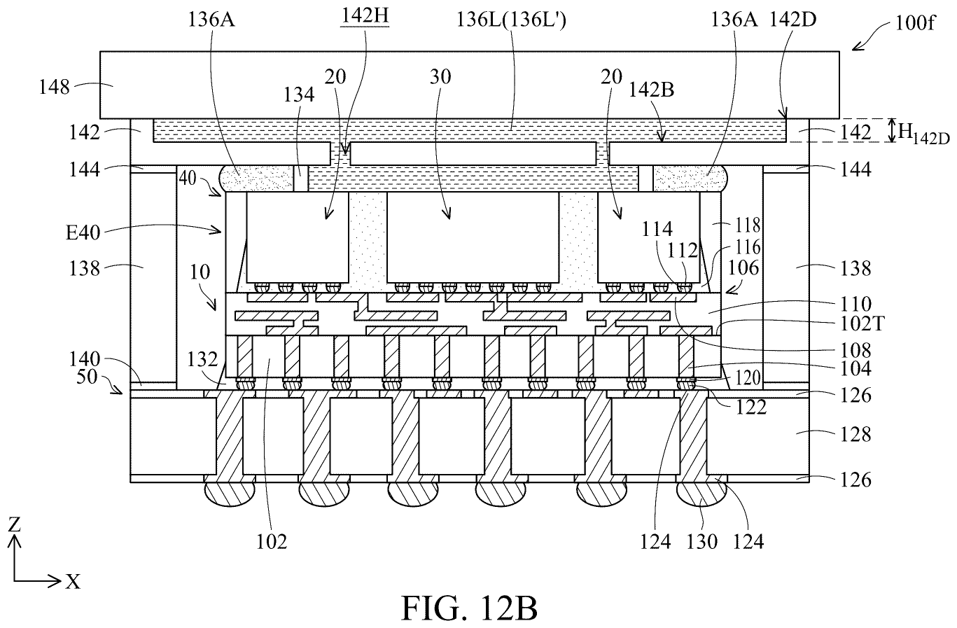

FIGS. 12A and 12B illustrate cross-sectional views of intermediate stages of manufacturing a package structure 100f in accordance with some embodiments. The package structure 100f may be similar to the package structures 100 and 100′ described previously, except the TIM 136G is not used in accordance with some embodiments. Other processes and materials for forming the package structure 100f may be similar to, or the same as, those for forming the package structures 100 and 100′ described previously and are not repeated herein.

More specifically, the processes shown in FIGS. 1A to 1H are performed, and the TIM 136A is applied to the region outside the protruding feature 134, as shown in FIG. 12A in accordance with some embodiments. FIG. 12A-1 illustrates a top view of the TIM 136A around the protruding feature 134a over the package component 40 in accordance with some embodiments. FIG. 12A-2 illustrates a top view of the TIM 136A around the protruding feature 134b over the package component 40 in accordance with some embodiments. As shown in FIGS. 12A, 12A-1, and 12A-2, the location for forming the TIM 136G shown in FIGS. 1I, 1I-1, and 1I-2 are replaced by the TIM 136A, so that the manufacturing process may be simplified in accordance with some embodiments.

After the TIM 136A is formed, the processes shown in FIGS. 1J to 1Q are performed to form the package structure 100f, as shown in FIG. 12B in accordance with some embodiments. As shown in FIG. 12B, the space between the package component 40 and the bottom surface of the lid 142 outside the region R surrounded by the protruding feature 134 is fully filled with the TIM 136A in accordance with some embodiments. That is, the TIM 136A and the TIM 136L cover the opposite sidewalls of the protruding feature 134.

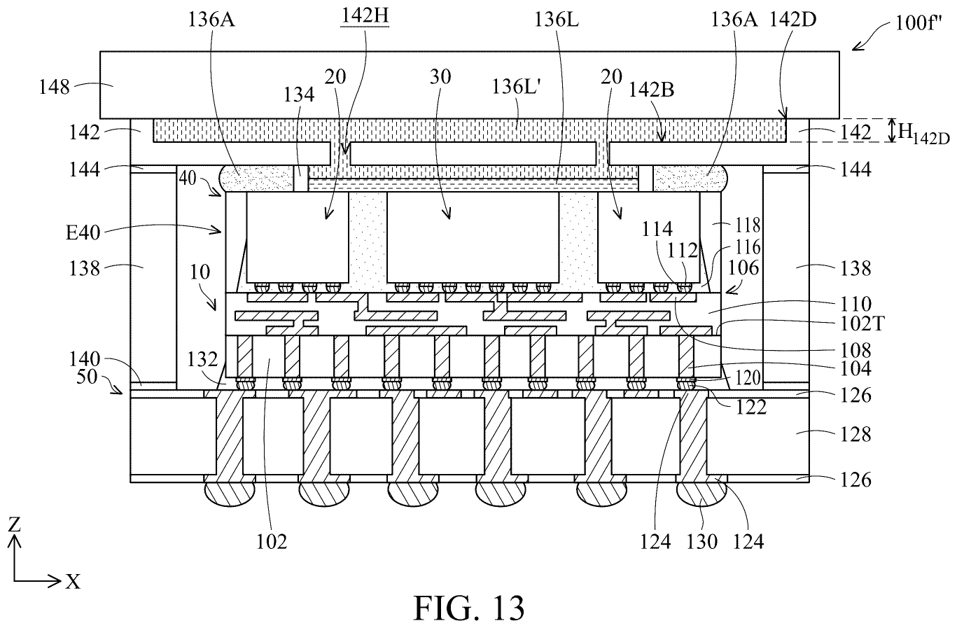

FIG. 13 illustrates a cross-sectional view of a package structure 100f″ in accordance with some embodiments. The package structure 100f″ may be similar to the package structure 100f described previously, except the processes shown in FIGS. 3A to 3C are applied in accordance with some embodiments. That is, the region R includes both the TIMs 136L and 136L′ in accordance with some embodiments. Other processes and materials for forming the package structure 100f″ may be similar to, or the same as, those for forming the package structure 100f described previously and are not repeated herein.

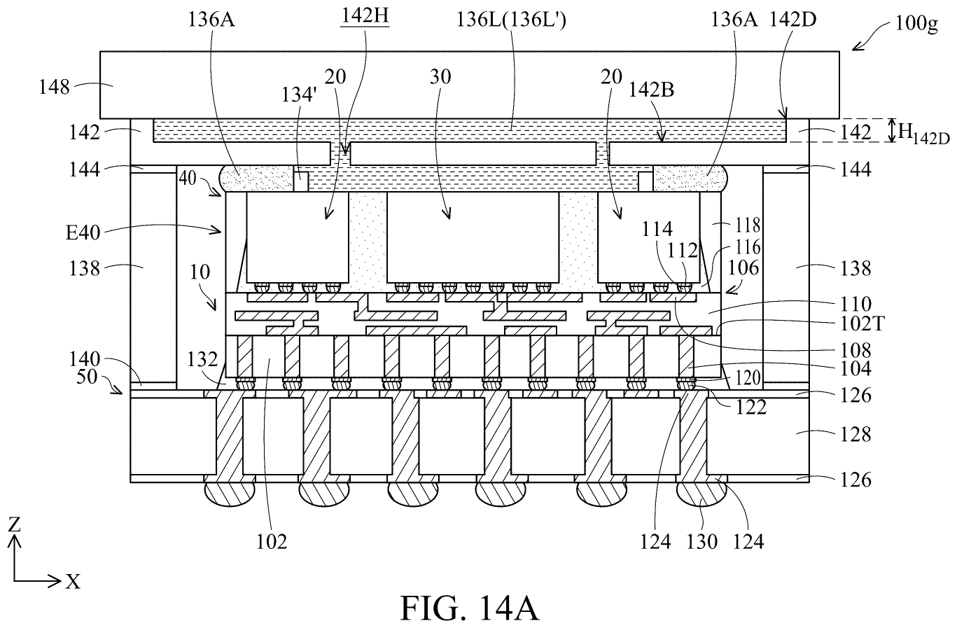

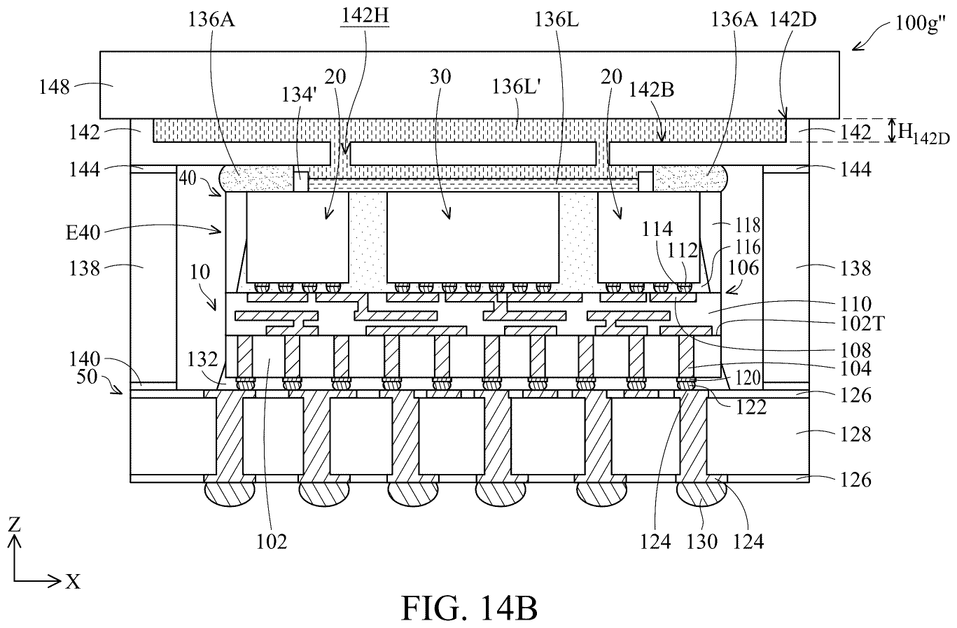

FIG. 14A illustrates a cross-sectional view of a package structure 100g in accordance with some embodiments. The package structure 100g may be similar to the package structure 100f described previously, except the protruding feature 134 is replaced by the protruding feature 134′ in accordance with some embodiments. Other processes and materials for forming the package structure 100g may be similar to, or the same as, those for forming the package structure 100f described previously and are not repeated herein. In addition, the processes for forming the protruding feature 134′ are the same as those shown in FIGS. 8A to 8C and described previously and therefore are not repeated herein.

As shown in FIG. 14A, the gap between the top surface of the protruding feature 134′ and the bottom surface of the lid 142 is filled by the TIM 136L (or 136L′) in accordance with some embodiments. That is, the top surface of the protruding feature 134′ is covered by the TIM 136L. In some embodiments, the interface between the TIM 136L and the TIM 136A is substantially aligned with an outer sidewall of the protruding feature 134′.

FIG. 14B illustrates a cross-sectional view of a package structure 100g″ in accordance with some embodiments. The package structure 100g″ may be similar to the package structure 100g described previously, except the processes shown in FIGS. 3A to 3C are applied in accordance with some embodiments. That is, the region R includes both the TIMs 136L and 136L′ in accordance with some embodiments. Other processes and materials for forming the package structure 100g″ may be similar to, or the same as, those for forming the package structure 100g described previously and are not repeated herein.

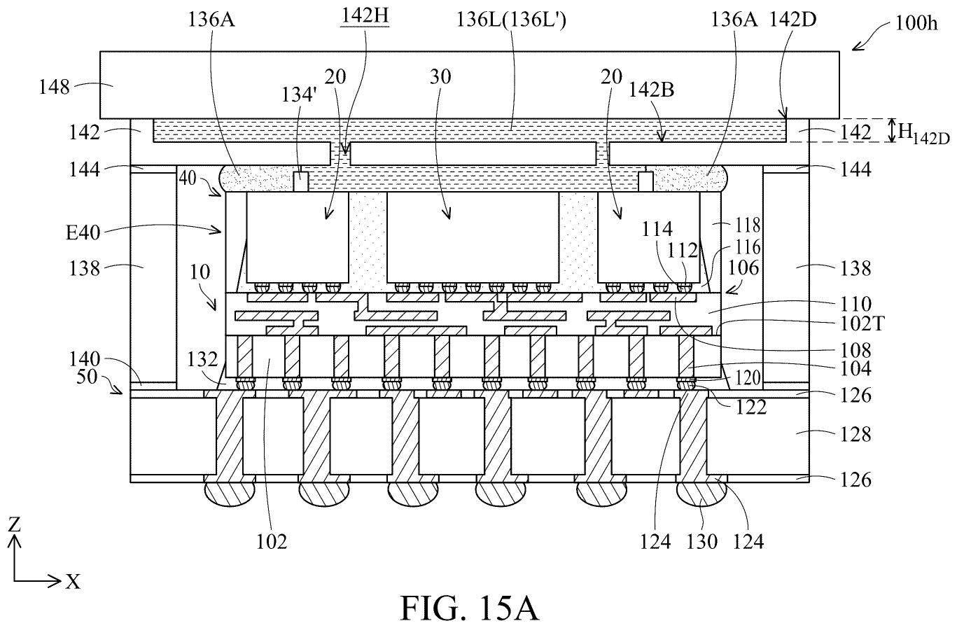

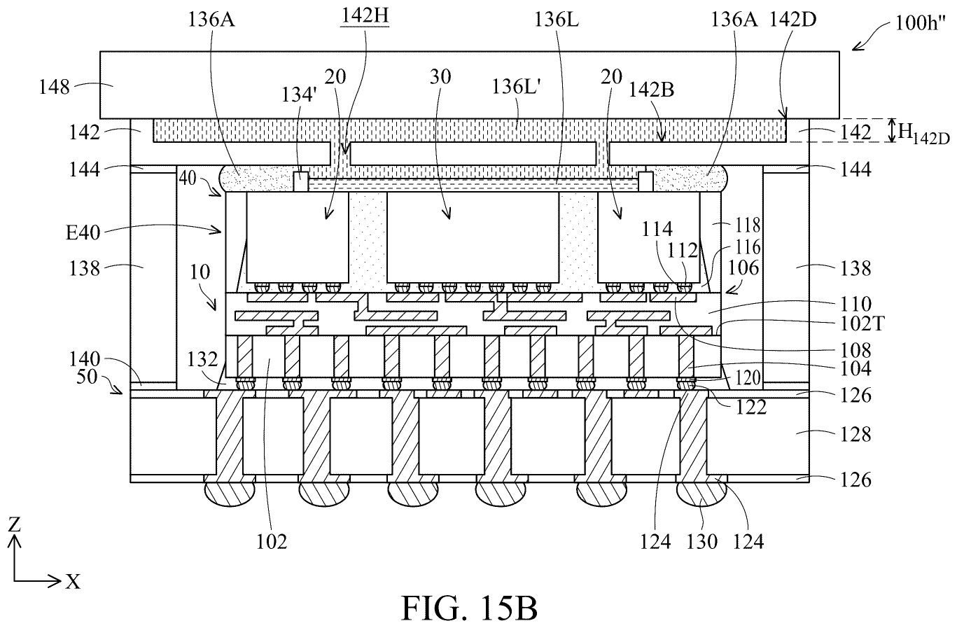

FIG. 15A illustrates a cross-sectional view of a package structure 100h in accordance with some embodiments. The package structure 100h may be similar to the package structure 100g described previously, except the top surface of the protruding feature 134′ is covered by both the TIMs 136A and 136L (or 136L′) in accordance with some embodiments. More specifically, the top surface of the protruding feature 134a is partially covered by the TIM 136A and partially covered by the TIM 136L in accordance with some embodiments. In some embodiments, the interface between the TIM 136A and the TIM 136L is over the top surface of the protruding feature 134′. Other processes and materials for forming the package structure 100h may be similar to, or the same as, those for forming the package structure 100g described previously and are not repeated herein.

FIG. 15B illustrates a cross-sectional view of a package structure 100h″ in accordance with some embodiments. The package structure 100h″ may be similar to the package structure 100h described previously, except the processes shown in FIGS. 3A to 3C are applied in accordance with some embodiments. That is, the region R includes both the TIMs 136L and 136L′ in accordance with some embodiments. Other processes and materials for forming the package structure 100h″ may be similar to, or the same as, those for forming the package structure 100h described previously and are not repeated herein.

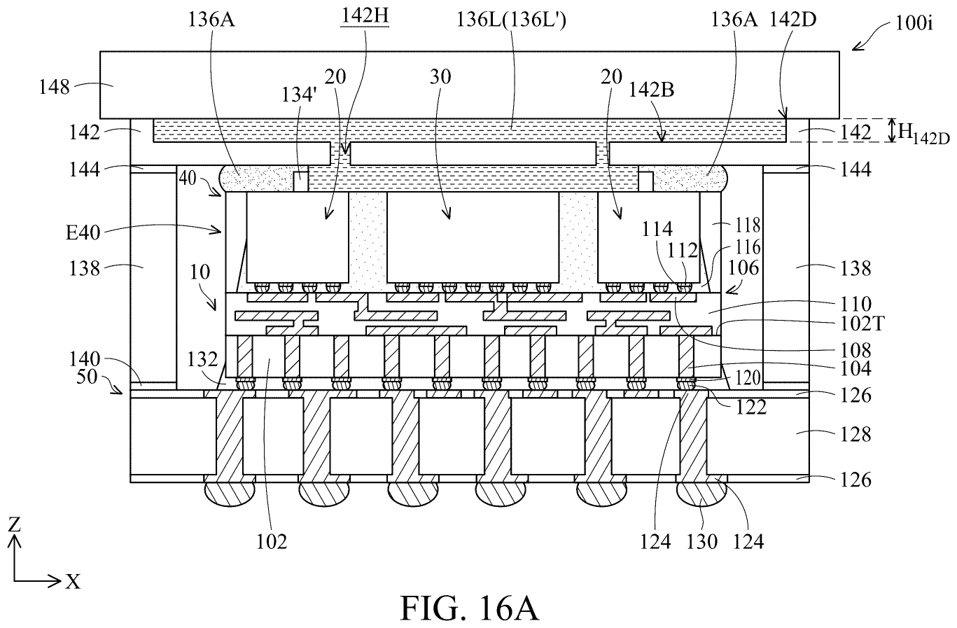

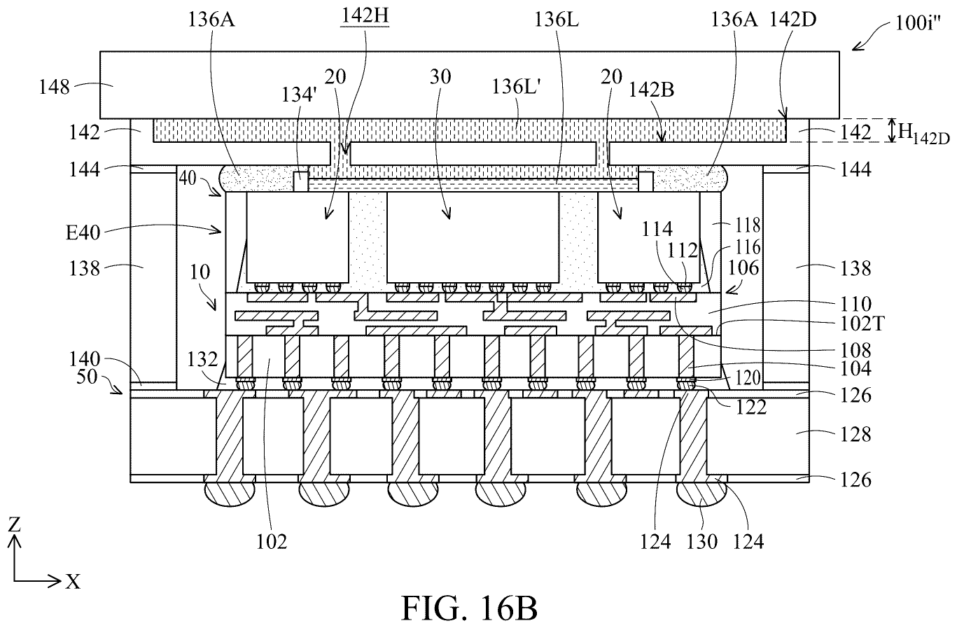

FIG. 16A illustrates a cross-sectional view of a package structure 100i in accordance with some embodiments. The package structure 100i may be similar to the package structure 100g described previously, except the top surface of the protruding feature 134′ is covered by the TIM 136A in accordance with some embodiments. More specifically, the gap between the top surface of the protruding feature 134′ and the bottom surface of the lid 142 is filled by the TIM 136A in accordance with some embodiments. That is, the top surface of the protruding feature 134′ is covered by the TIM 136A. In some embodiments, the interface between the TIM 136L and the TIM 136A is substantially aligned with an inner sidewall of the protruding feature 134′. Other processes and materials for forming the package structure 100i may be similar to, or the same as, those for forming the package structure 100g described previously and are not repeated herein.

FIG. 16B illustrates a cross-sectional view of a package structure 100i″ in accordance with some embodiments. The package structure 100i″ may be similar to the package structure 100i described previously, except the processes shown in FIGS. 3A to 3C are applied in accordance with some embodiments. That is, the region R includes both the TIMs 136L and 136L′ in accordance with some embodiments. Other processes and materials for forming the package structure 100i″ may be similar to, or the same as, those for forming the package structure 100i described previously and are not repeated herein.

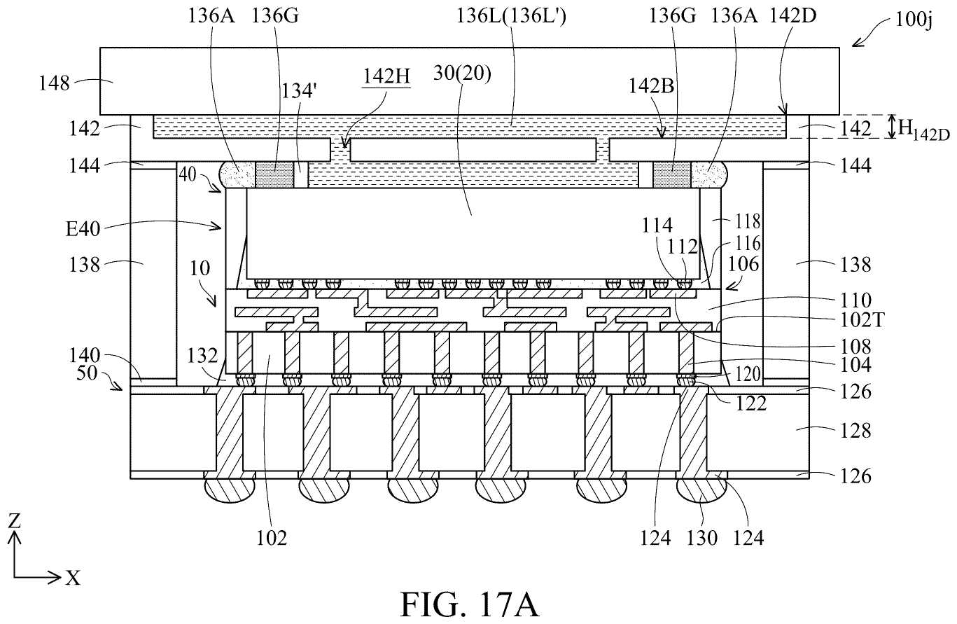

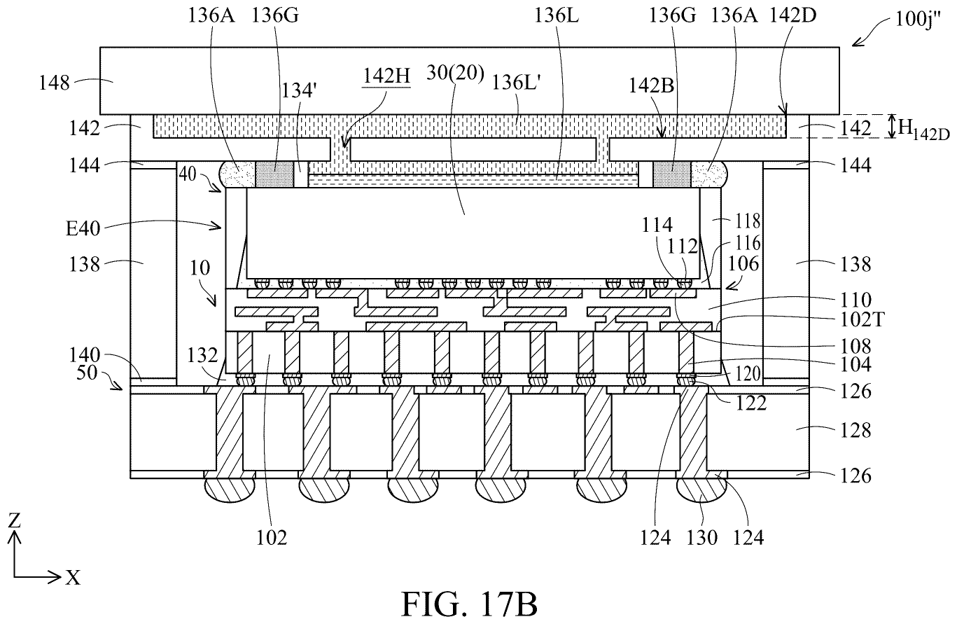

FIG. 17A illustrates a cross-sectional view of a package structure 100j in accordance with some embodiments. The package structure 100j may be similar to the package structures 100 and 100′ described previously, except the structure is applied to a single semiconductor die 30 (or 20) in accordance with some embodiments. More specifically, the protruding feature 134 is attached to a single semiconductor die 30 in accordance with some embodiments. That is, the TIMs 136A and 136G are formed over a periphery region of the semiconductor die 30 and the TIM 136L (or 136L′) is formed over a central region of the semiconductor die 30 in accordance with some embodiments.

FIG. 17B illustrates a cross-sectional views of a package structure 100j″ in accordance with some embodiments. The package structure 100j″ may be similar to the package structure 100j described previously, except the processes shown in FIGS. 3A to 3C are applied in accordance with some embodiments. That is, the region R includes both the TIMs 136L and 136L′ in accordance with some embodiments. Other processes and materials for forming the package structure 100j″ may be similar to, or the same as, those for forming the package structure 100j described previously and are not repeated herein.

As described above, in an advanced package device, such as a CoWoS package or other advanced high-power package device, heat dissipation become an important issue since these types of devices may be high power consumption and therefore be high heat generated devices. Accordingly, in some embodiments of the present disclosure, the TIM 136L (or 136L′), which is a liquid TIM, is applied to the package structures 100 to 100j″ so that the heat dissipation of the package structures can be improved. In addition, the protruding feature 134 is applied to the package component 40, so that the TIM 136L can be confined within the region surrounded by the protruding feature 134 and over the semiconductor dies 20 and 30 in accordance with some embodiments. Therefore, the heat generated by the semiconductor dies 20 and 30 may be efficiently spread to the external cooling tool 148 in accordance with some embodiments.

Furthermore, the TIMs 136A and 136G having relatively lower fluidity are formed at the periphery regions of the package component 40, so that the risk of the overflow issue due to the high fluidity of the liquid TIM 136L can be further reduced. Accordingly, the performance of the resulting package structures may have an improved performance due to the improved heat dissipation ability, while the reliability will not be undermined due to the usage of the liquid TIM.

In addition, the lid is designed having a shape that can contain the TIM 136L to be in direct contact with both the external cooling tool 148 and the package component 40 in accordance with some embodiments. In addition, the TIM 136L can be applied and removed from these two regions of the lid 142 easily in accordance with some embodiments. That is, the package structures may be easily assemble and disassemble to apply and replace the TIM 136L, and the performance of the resulting device may have a better performance and an extended life cycle accordingly.

It should be appreciated that the elements shown in the package structures 100, 100′, 100″, 100a, 100a″, 100b, 100b″, 100c′ 100c″, 100d, 100d″, 100e, 100e″, 100f, 100f″, 100g, 100g″, 100h, 100h″, 100i, 100i″, 100j, and 100j″ may be combined and/or exchanged. For example, the protruding feature 134 in the package structures described above may have the shape shown in FIGS. 1H-1 to 1H-4. Similarly, the semiconductor die 20/30 in the package structures described above may have the layout shown in FIG. 1B-1 or 1B-2 or may be a single die shown in FIGS. 17A and 17B.

In addition, it should be noted that same elements in FIGS. 1A to 17B may be designated by the same numerals and may include materials that are the same or similar and may be formed by processes that are the same or similar; therefore such redundant details are omitted in the interests of brevity. In addition, although FIGS. 1A to 17B are described in relation to the method, it will be appreciated that the structures disclosed in FIGS. 1A to 17B are not limited to the method but may stand alone as structures independent of the method. Similarly, the methods shown in FIGS. 1A to 17B are not limited to the disclosed structures but may stand alone independent of the structures.

Also, while the disclosed methods are illustrated and described above as a series of acts or events, it should be appreciated that the illustrated ordering of such acts or events may be altered in some other embodiments. For example, some acts may occur in a different order and/or concurrently with other acts or events apart from those illustrated and/or described above. In addition, not all illustrated acts may be required to implement one or more aspects or embodiments of the description above. Furthermore, one or more of the acts depicted above may be carried out as one or more separate acts and/or phases. Furthermore, the terms “approximately,” “substantially,” “substantial” and “about” used above account for small variations and may be varied in different technologies and be within the deviation range understood by the skilled in the art.

Embodiments of package structures may be provided. The package structure may include a package component and a protruding feature formed over the package component. In addition, a lid may be disposed over the protruding feature, and a TIM with high fluidity and high thermal conductivity may be applied to the region surrounded by the protruding feature. The TIM may help dissipate the heat generated in the package component, and therefore the temperature of the device during operation may be reduced, and the performance may be improved.

A package structure is provided. The package structure includes a package component and a protruding feature attached to the package component. The package structure further includes a lid disposed over the package component and the protruding feature and a first thermal interface material under a bottom surface of the lid and at a first side of the protruding feature. The package structure includes a second thermal interface material. In addition, the second thermal interface material includes a first portion under the bottom surface of the lid and at a second side of the protruding feature, a second portion over a bottom portion of the lid, and a third portion through the bottom portion of the lid and connecting with the first portion and the second portion.

A package structure is provided. The package structure includes an interposer structure and a first semiconductor die disposed over the interposer structure. The package structure further includes a lid disposed over the first semiconductor die. In addition, the lid includes a bottom portion and a dam portion attaching to an edge of the bottom portion. The package structure further includes a protruding feature protruding from a top surface of the first semiconductor die and a liquid thermal interface material over the first semiconductor die. In addition, the liquid thermal interface material includes a first portion surrounded by the protruding feature, a second portion surrounded by the dam portion of the lid over the bottom portion of the lid, and a third portion in the bottom portion of the lid.

A method for manufacturing a package structure is provided. The method for manufacturing the package structure includes disposing a semiconductor die over an interposer structure and encapsulating the semiconductor die in a molding layer. The method for manufacturing the package structure further includes forming a protruding feature over the semiconductor die, and the protruding feature surrounds a first region. The method for manufacturing the package structure further includes applying a first thermal interface material over the molding layer in a second region that is outside the first region and disposing a lid over the protruding feature and the first thermal interface material. In addition, the lid includes a first trench surrounded by a dam portion of the lid and a first perforated hole penetrating through a bottom portion of the lid. The method for manufacturing the package structure further includes filling the first region, the first perforated hole, and the first trench with a second thermal interface material and disposing an external cooling tool over the dam portion of the lid.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a package component;
a protruding feature attached to the package component;
a lid disposed over the package component and the protruding feature;
a first thermal interface material under a bottom surface of the lid and at a first side of the protruding feature; and
a second thermal interface material, wherein the second thermal interface material comprises:
a first portion under the bottom surface of the lid and at a second side of the protruding feature;
a second portion over a bottom portion of the lid; and
a third portion through the bottom portion of the lid and connecting with the first portion and the second portion.

2. The package structure as claimed in claim 1, wherein a fluidity of the second thermal interface material is greater than a fluidity of the first thermal interface material.

3. The package structure as claimed in claim 1, wherein the first portion of the second thermal interface material is surrounded by the protruding feature in a top view.

4. The package structure as claimed in claim 1, further comprising:
a third thermal interface material laterally sandwiched between the protruding feature and the first thermal interface material, wherein a fluidity of the third thermal interface material is greater than a fluidity of the first thermal interface material.

5. The package structure as claimed in claim 4, further comprising:
a fourth thermal interface material under the second thermal interface material.

6. The package structure as claimed in claim 1, wherein the protruding feature comprises protruding units separated from each other.

7. A package structure, comprising:
an interposer structure;
a first semiconductor die disposed over the interposer structure;
a lid disposed over the first semiconductor die, wherein the lid comprises a bottom portion and a dam portion attaching to an edge of the bottom portion;
a protruding feature protruding from a top surface of the first semiconductor die;
a liquid thermal interface material over the first semiconductor die, wherein the liquid thermal interface material comprises:
a first portion surrounded by the protruding feature;
a second portion surrounded by the dam portion of the lid over the bottom portion of the lid; and
a third portion in the bottom portion of the lid.

8. The package structure as claimed in claim 7, further comprising:
a first thermal interface material under the bottom surface of the bottom portion of the lid, wherein the first thermal interface material and the liquid thermal interface material cover opposite sidewalls of the protruding feature.

9. The package structure as claimed in claim 8, wherein a top surface of the protruding feature is at least partially covered by the first thermal interface material or the liquid thermal interface material.

10. The package structure as claimed in claim 8, wherein the first thermal interface material is in contact with the liquid thermal interface material.

11. The package structure as claimed in claim 8, further comprising:
a second thermal interface material under the bottom surface of the bottom portion of the lid, wherein the first thermal interface material is sandwiched between the second thermal interface material and the protruding feature.

12. The package structure as claimed in claim 7, further comprising:
an externa cooling tool attached to the dam portion of the lid, wherein the second portion of the liquid thermal interface material covers a bottom surface of the externa cooling tool.

13. The package structure as claimed in claim 7, further comprising:
a second semiconductor die disposed over the interposer structure, wherein the protruding feature extends from a top surface of the first semiconductor die to a top surface of the second semiconductor die.

14. A method for manufacturing a package structure, comprising:
disposing a semiconductor die over an interposer structure;
encapsulating the semiconductor die in a molding layer;
forming a protruding feature over the semiconductor die, wherein the protruding feature surrounds a first region;
applying a first thermal interface material over the molding layer in a second region that is outside the first region;
disposing a lid over the protruding feature and the first thermal interface material, wherein the lid comprises a first trench surrounded by a dam portion of the lid and a first perforated hole penetrating through a bottom portion of the lid, and the first perforated hole is inside a projection area of the first region in a top view;
filling the first region, the first perforated hole, and the first trench with a second thermal interface material; and
disposing an external cooling tool over the dam portion of the lid.

15. The method for manufacturing the package structure as claimed in claim 14, further comprising:
removing the external cooling tool;
at least partially replacing the second thermal interface material by a third thermal interface material; and
disposing the external cooling tool over the lid after replacing the second thermal interface material by the third thermal interface material.

16. The method for manufacturing the package structure as claimed in claim 15, further comprising:
at least partially removing the second thermal interface material in the first region through the first perforated hole of the lid.

17. The method for manufacturing the package structure as claimed in claim 15, further comprising:
applying a third thermal interface material over the semiconductor die before disposing the lid over the protruding feature, wherein a thermal conductivity of the second thermal interface material is greater than a thermal conductivity of the third thermal interface material, and the thermal conductivity of the third thermal interface material is greater than a thermal conductivity of the first thermal interface material.

18. The method for manufacturing the package structure as claimed in claim 14, wherein the lid further comprise a second perforated hole penetrating through the bottom portion of the lid, and the second perforated hole is also inside the projection area of the first region in the top view.

19. The method for manufacturing the package structure as claimed in claim 14, wherein a top surface of the first thermal interface material is higher than a top surface of the protruding feature before disposing the lid over the protruding feature and the first thermal interface material.

20. The method for manufacturing the package structure as claimed in claim 14, wherein a height of the protruding feature is substantially equal to or smaller than a distance between a top surface of the semiconductor die and a bottom surface of the bottom portion of the lid.
